(19) United States
(12) Patent Application Publication
(10) Pub. No.: US 2025/0329645 A1
(43) Pub. Date: Oct. 23, 2025

(54) SEMICONDUCTOR DEVICE, MANUFACTURING METHOD THEREOF, AND MEMORY SYSTEM

(71) Applicant: YANGTZE MEMORY TECHNOLOGIES CO., LTD., Wuhan (CN)

(72) Inventors: Zongliang Huo, Wuhan (CN); Wenbin Zhou, Wuhan (CN); Wei Xu, Wuhan (CN); Bin Yuan, Wuhan (CN)

(21) Appl. No.: 18/790,656

(22) Filed: Jul. 31, 2024

(30) Foreign Application Priority Data
Apr. 17, 2024 (CN) 202410468485.0

(51) Int. Cl. H01L 23/528; H01L 23/522; H01L 23/532; H01L 25/065; H01L 29/423; H10B 12/00; H10B 80/00

(52) U.S. Cl. CPC H01L 23/5283; H01L 23/5226; H01L 23/528; H01L 23/53271; H10B 12/0335; H10B 12/05; H10B 12/315; H10B 12/482; H10D 64/513; H10D 64/518; H01L 25/0657; H01L 2225/06544; H01L 2225/06551; H10B 80/00

(57) ABSTRACT

According to one aspect of the present disclosure, a semiconductor device is provided. The semiconductor device may include a semiconductor structure including a semiconductor body extending along a first direction. The semiconductor device may include a conductive structure located on a side of the semiconductor body along the first direction. The conductive structure may include a first part and a second part arranged along a second direction. The first part may be in contact with an end of the semiconductor body. A size of a portion of the first part close to the second part in a third direction may be different from a size of a portion of the second part close to the first part in the third direction. The second direction may intersect the third direction, and the first direction may be perpendicular to a plane formed by the second direction and the third direction.

### CROSS-REFERENCE TO RELATED APPLICATIONS

The present application claims the benefit of priority to Chinese Application No. 202410468485.0, filed on Apr. 17, 2024, which is hereby incorporated by reference in its entirety.

### TECHNICAL FIELD

The present disclosure relates to the field of semiconductor technology, and in particular, to a semiconductor device, a manufacturing method thereof, and a memory system.

### BACKGROUND

A semiconductor device, e.g., a dynamic random access memory (DRAM), is one of the most important data access components in an electronic system. Typically, one transistor (T) and one capacitor (C) are employed to constitute a 1T1C structure as one memory cell. This 1T1C structure enables the dynamic random access memory to have a high integration level and a low cost, and plays an irreplaceable role in a computer access device. With the rapid development of semiconductor technology, the dynamic random access memory is rapidly developing towards high density and high quality.

### SUMMARY

According to one aspect of the present disclosure, a semiconductor device is provided. The semiconductor device may include a semiconductor structure including a semiconductor body extending along a first direction. The semiconductor device may include a conductive structure located on a side of the semiconductor body along the first direction. The conductive structure may include a first part and a second part arranged along a second direction. The first part may be in contact with an end of the semiconductor body. A size of a portion of the first part close to the second part in a third direction may be different from a size of a portion of the second part close to the first part in the third direction. The second direction may intersect the third direction, and the first direction may be perpendicular to a plane formed by the second direction and the third direction.

In some implementations, the size of the portion of the first part close to the second part in the third direction is a first size. In some implementations, the size of the portion of the second part close to the first part in the third direction is a second size. In some implementations, the second size is greater than the first size.

In some implementations, a cross-sectional shape of the first part in the plane may include a square. In some implementations, a cross-sectional shape of the second part in the plane may include an axisymmetric shape having a curved edge.

In some implementations, a spacing distance in the second direction between a surface of the first part away from the second part in the second direction and a surface of the semiconductor body away from the second part in the second direction may be less than a preset value.

In some implementations, the semiconductor device may include a gate structure located on a side of the semiconductor body close to the second part in the second direction. In some implementations, a surface of the gate structure close to the second part along the first direction may be spaced apart from a surface of the second part close to the gate structure along the first direction.

In some implementations, the semiconductor structure may further include a first isolation structure located on a side of the semiconductor body away from the second part in the second direction. In some implementations, the semiconductor structure may further include a second isolation structure located on a side of the gate structure away from the semiconductor body along the second direction. In some implementations, the second isolation structure may be in contact with a surface of the second part away from the first part, the surface of the second part close to the gate structure along the first direction, and the surface of the gate structure close to the second part along the first direction.

In some implementations, the second isolation structure may be a first sub-structure and a second sub-structure arranged along the first direction. In some implementations, the first sub-structure may be located on the side of the gate structure away from the semiconductor body along the second direction. In some implementations, the second sub-structure may be located on a side of the second part away from the first part, and located between the surface of the gate structure close to the second part along the first direction and the surface of the second part close to the gate structure along the first direction.

In some implementations, the second isolation structure may include a first sub-structure, a third sub-structure and a fourth sub-structure arranged along the first direction. In some implementations, the first sub-structure may be located on the side of the gate structure away from the semiconductor body along the second direction. In some implementations, the third sub-structure may be located between the surface of the gate structure close to the second part along the first direction and the surface of the second part close to the gate structure along the first direction. In some implementations, the fourth sub-structure may be located on a side of the second part away from the first part.

In some implementations, a composition material of the third sub-structure may be different from a composition material of the fourth sub-structure.

In some implementations, a size of the second part along the second direction may be less than a size of the third sub-structure along the second direction.

In some implementations, the side of the second part away from the first part along the second direction may be a straight line side extending along the third direction.

In some implementations, the conductive structure may be located between the first isolation structure and the fourth sub-structure, and may be in contact with a side of the third sub-structure away from the gate structure along the first direction.

In some implementations, the first isolation structure may include a first end face and a second end face that are opposite along the first direction, and the second isolation structure may include a third end face and a fourth end face that are opposite along the first direction. In some implementations, the first end face, the third end face, a surface of the first part away from the semiconductor body along the first direction, and a surface of the second part away from the gate structure along the first direction may be aligned along the second direction.

In some implementations, the conductive structure may include a polysilicon layer, a metal silicide layer and a conductive metal layer stacked along the first direction. In some implementations, the conductive structure may include a polysilicon layer and a metal silicide layer stacked along the first direction. In some implementations, the conductive structure may include a metal silicide layer in contact with the semiconductor body.

In some implementations, the semiconductor body may include a channel region. In some implementations, the semiconductor body may include a source and a drain located on two sides of the channel region respectively along the first direction.

In some implementations, the semiconductor structure may further include a capacitor structure connected with an end of the conductive structure away from the semiconductor body in the first direction.

In some implementations, the capacitor structure may include a fifth end face and a sixth end face that are opposite along the first direction. In some implementations, a surface of the first part away from the semiconductor body along the first direction and at least part of a surface of the second part away from the semiconductor body along the first direction are in contact with the fifth end face.

In some implementations, the semiconductor device may further include a plurality of the semiconductor structures arranged in an array along the second direction and the third direction. In some implementations, the plurality of the semiconductor structures arranged along the second direction may include a first semiconductor structure and a second semiconductor structure arranged alternately. In some implementations, the first semiconductor structure and the second semiconductor structure disposed adjacently constitute one semiconductor structure group.

In some implementations, the first semiconductor structure may include a first semiconductor body, a first gate structure and a first conductive structure. In some implementations, the second semiconductor structure may include a second semiconductor body, a second gate structure and a second conductive structure. In some implementations, the first gate structure may be located on a side of the first semiconductor body close to the second semiconductor body, and the second gate structure may be located on a side of the second semiconductor body close to the first gate structure. In some implementations, a second part of the first conductive structure may be located on a side of a first part of the first conductive structure close to the second conductive structure, and a second part of the second conductive structure may be located on a side of a first part of the second conductive structure close to the first conductive structure.

In some implementations, a plurality of bit lines extending along the second direction and spaced apart along the third direction. In some implementations, each of the plurality of bit lines may be connected with an end of one row of the semiconductor bodies away from the conductive structure along the first direction.

According to another aspect of the present disclosure, a memory system is provided. The memory system may include a semiconductor device. The semiconductor device may include a semiconductor structure including a semiconductor body extending along a first direction. The semiconductor device may include a conductive structure located on a side of the semiconductor body along the first direction. The conductive structure may include a first part and a second part arranged along a second direction. The first part may be in contact with an end of the semiconductor body. A size of a portion of the first part close to the second part in a third direction may be different from a size of a portion of the second part close to the first part in the third direction. The second direction intersects the third direction, and the first direction may be perpendicular to a plane formed by the second direction and the third direction. The memory system may include a memory controller connected with the semiconductor device and configured to control the semiconductor device.

According to a further aspect of the present disclosure, a method of manufacturing of a semiconductor device is provided. The method may include forming a semiconductor body extending along a first direction. The method may include forming a conductive structure located on a side of the semiconductor body along the first direction. The semiconductor body and the conductive structure may be configured to form a semiconductor structure. The conductive structure may include a first part and a second part arranged along a second direction. The first part may be in contact with an end of the semiconductor body. A size of a portion of the first part close to the second part in a third direction may be different from a size of a portion of the second part close to the first part in the third direction. The second direction may intersect the third direction, and the first direction may be perpendicular to a plane formed by the second direction and the third direction.

In some implementations, the forming a semiconductor body extending along a first direction may include forming, in a semiconductor layer, a plurality of first grooves extending along the second direction and spaced apart along the third direction, and a plurality of second grooves and a plurality of third grooves extending along the third direction and alternately spaced apart along the second direction, to form a plurality of semiconductor pillars extending along the first direction, the semiconductor pillars being configured to form the semiconductor body. In some implementations, the forming a semiconductor body extending along a first direction may include forming a first isolation structure in the second groove. In some implementations, the forming a semiconductor body extending along a first direction may include forming a gate material layer in the third groove, wherein the gate material layer covers part of a surface of the semiconductor pillar and covers an exposed bottom surface of the semiconductor layer. In some implementations, the forming a semiconductor body extending along a first direction may include forming a first sub-structure on a side of the gate material layer away from the semiconductor pillar along the second direction.

In some implementations, the method may include filling the third grooves with a first dielectric layer, wherein the first dielectric layer covers a remaining surface of the semiconductor pillar and covers surfaces of the gate material layer and the first sub-structure away from the bottom surface of the semiconductor layer along the first direction.

In some implementations, the method may include removing part of the semiconductor pillar to form a fourth groove. In some implementations, a size of a remaining semiconductor pillar along the first direction may be greater than a size of the gate material layer along the first direction.

In some implementations, the method may include removing part of the first dielectric layer to form a fifth groove having a curved edge. In some implementations, a remaining first dielectric layer may constitute a second sub-structure. In some implementations, the first sub-structure and the second sub-structure may constitute a second isolation structure.

In some implementations, the forming the conductive structure may include forming the first part of the conductive structure in the fourth groove and forming the second part of the conductive structure in the fifth groove. In some implementations, the first part may be in contact with an end of the remaining semiconductor pillar.

In some implementations, the forming the conductive structure in the fourth groove and the fifth groove may include forming a polysilicon layer in the fourth groove and the fifth groove. In some implementations, the polysilicon layer may be in contact with an end of the remaining semiconductor pillar. In some implementations, the forming the conductive structure in the fourth groove and the fifth groove may include forming a metal silicide layer on a side of the polysilicon layer away from the remaining semiconductor pillar. In some implementations, the forming the conductive structure in the fourth groove and the fifth groove may include forming a conductive metal layer on a side of the metal silicide layer away from the polysilicon layer.

In some implementations, the forming the conductive structure in the fourth groove and the fifth groove may include forming a polysilicon layer in the fourth groove and the fifth groove, wherein the polysilicon layer is in contact with an end of the remaining semiconductor pillar. In some implementations, the forming the conductive structure in the fourth groove and the fifth groove may include forming a metal silicide layer on a side of the polysilicon layer away from the remaining semiconductor pillar.

In some implementations, the forming the conductive structure in the fourth groove and the fifth groove may include forming a polysilicon layer in the fourth groove and the fifth groove. In some implementations, the forming the conductive structure in the fourth groove and the fifth groove may include metallizing the polysilicon layer to obtain a metal silicide, to form the conductive structure.

In some implementations, the method may include forming a second dielectric layer in the third grooves. In some implementations, the second dielectric layer may cover a remaining surface of the semiconductor pillar and covers the surfaces of the gate material layer and the first sub-structure away from the bottom surface of the semiconductor layer along the first direction. In some implementations, the method may include forming a fourth sub-structure on a side of the second dielectric layer away from the semiconductor pillar along the second direction.

In some implementations, the method may include removing part of the semiconductor pillar to form a sixth groove. In some implementations, a size of a remaining semiconductor pillar along the first direction may be greater than a size of the gate material layer along the first direction.

In some implementations, the method may include removing part of the second dielectric layer to form a seventh groove having a curved edge. In some implementations, a remaining second dielectric layer may constitute a third sub-structure. In some implementations, the first sub-structure, the third sub-structure and the fourth sub-structure may constitute a second isolation structure.

In some implementations, a composition material of the third sub-structure may be different from a composition material of the fourth sub-structure.

In some implementations, a size of the second part along the second direction may be less than a size of the third sub-structure along the second direction.

In some implementations, the side of the second part away from the first part along the second direction may be a straight line side extending along the third direction.

In some implementations, the forming the conductive structure may include forming a first part of the conductive structure in the sixth groove and forming a second part of the conductive structure in the seventh groove. In some implementations, the first part is in contact with an end of the remaining semiconductor pillar.

In some implementations, the removing may include wet etching.

In some implementations, the first isolation structure may include a first end face and a second end face that are opposite along the first direction, and the second isolation structure may include a third end face and a fourth end face that are opposite along the first direction. In some implementations, the first end face, the third end face, a surface of the first part away from the semiconductor body along the first direction, and a surface of the second part away from a gate structure along the first direction are aligned along the second direction.

In some implementations, the size of the portion of the first part close to the second part in the third direction may be a first size. In some implementations, the size of the portion of the second part close to the first part in the third direction may be a second size. In some implementations, the second size may be greater than the first size.

In some implementations, the method may further include removing the gate material layer covering the bottom surface of the semiconductor layer to form a gate structure.

In some implementations, the method may further include forming a capacitor structure connected with an end of the conductive structure away from the semiconductor body along the first direction.

In some implementations, the method may further include doping a first end of the remaining semiconductor pillar away from the bottom surface of the semiconductor layer along the first direction before forming the capacitor structure, to form one of a source or a drain. In some implementations, the method may further include thinning the semiconductor layer after forming the capacitor structure to expose a second end of the remaining semiconductor pillar opposite to the first end along the first direction. In some implementations, the method may further include doping the second end to form the other one of the source or the drain. In some implementations, a region of the remaining semiconductor pillar between the source and the drain may constitute a channel region; and the channel region, the source and the drain constitute the semiconductor body.

In some implementations, the capacitor structure may include a fifth end face and a sixth end face that are opposite along the first direction. In some implementations, a surface of the first part away from the semiconductor body along the first direction and at least part of a surface of the second part away from the semiconductor body along the first direction are in contact with the fifth end face.

In some implementations, the method may include forming a plurality of the semiconductor structures arranged in an array along the second direction and the third direction. In some implementations, the plurality of semiconductor structures arranged along the second direction may include a first semiconductor structure and a second semiconductor structure arranged alternately. In some implementations, the first semiconductor structure and the second semiconductor structure disposed adjacently constitute one semiconductor structure group.

In some implementations, the forming a plurality of the semiconductor structures arranged in an array along the second direction and the third direction may include forming a first gate structure on a side of a first semiconductor body close to a second semiconductor body, and forming a first conductive structure on a side of the first semiconductor body along the first direction to form the first semiconductor structure. In some implementations, the forming a plurality of the semiconductor structures arranged in an array along the second direction and the third direction may include forming a second gate structure on a side of the second semiconductor body close to the first gate structure, and forming a second conductive structure on a side of the second semiconductor body along the first direction to form the second semiconductor structure.

In some implementations, the method may include forming a plurality of bit lines extending along the second direction and spaced apart along the third direction. In some implementations, each of the plurality of bit lines may be connected with an end of one row of the semiconductor bodies away from the conductive structure along the first direction.

Examples of the present disclosure provide a semiconductor device, a manufacturing method thereof, and a memory system, wherein the manufacturing method of the semiconductor device, comprising: forming a semiconductor body extending along a first direction; and forming a conductive structure located on a side of the semiconductor body along the first direction, the semiconductor body and the conductive structure being configured to form a semiconductor structure, wherein the conductive structure comprises a first part and a second part arranged along a second direction; the first part is in contact with an end of the semiconductor body; a size of a portion of the first part close to the second part in a third direction is different from a size of a portion of the second part close to the first part in the third direction; the second direction intersects the third direction, and the first direction is perpendicular to a plane formed by the second direction and the third direction. In the examples of the present disclosure, by forming the conductive structure connected with the semiconductor body on a side of the semiconductor body along the first direction, self-alignment of the conductive structure and the semiconductor body can be achieved. As such, alignment accuracy of the first part of the conductive structure with the semiconductor body can be improved; alignment difficulty of them is reduced; reliability of the semiconductor device is improved; manufacturing time and cost are saved; and process speed and efficiency are increased. In another aspect, the conductive structure comprises the first part connected with the semiconductor body, and the second part arranged in juxtaposition with the first part along the second direction. As such, the purpose of increasing the volume/surface area of the conductive structure can be achieved; thus, the contact area of the conductive structure with other external structure (e.g., the capacitor structure) can be increased and the reliability of the semiconductor device can be improved. In further another aspect, the size of the portion of the first part close to the second part in the third direction is different from the size of the portion of the second part close to the first part in the third direction. As such, the conductive structure and the semiconductor body may have a better matched and more reasonable structure layout.

### BRIEF DESCRIPTION OF THE DRAWINGS

FIG. 1 is a schematic structure view of a dynamic random access memory provided by examples of the present disclosure;

FIGS. 2a to 2d are schematic diagrams of a manufacturing process of a conductive structure provided by examples of the present disclosure;

FIG. 3 is a flow diagram of a manufacturing method of a semiconductor device provided by examples of the present disclosure;

FIGS. 4a to 4b are schematic structure views of forming a first groove provided by examples of the present disclosure;

FIGS. 5a to 5b are schematic structure views of forming a first isolation structure provided by examples of the present disclosure;

FIG. 6 is a schematic structure view of forming an insulation material layer provided by examples of the present disclosure;

FIG. 7 is a schematic structure view of forming a gate material layer provided by examples of the present disclosure;

FIG. 8 is a schematic structure view of forming a first dielectric layer provided by examples of the present disclosure;

FIGS. 9a to 9b are schematic structure views of forming a fourth groove provided by examples of the present disclosure;

FIGS. 10a to 10b are schematic structure views of forming a fifth groove provided by examples of the present disclosure;

FIGS. 11a to 11b are schematic structure views of forming a conductive structure provided by examples of the present disclosure;

FIGS. 12a to 12b are schematic structure views of forming a fourth sub-structure provided by examples of the present disclosure;

FIGS. 13a to 13b are schematic structure views of forming a sixth groove provided by examples of the present disclosure;

FIGS. 14a to 14b are schematic structure views of forming a seventh groove provided by examples of the present disclosure;

FIGS. 15a to 15b are another schematic structure views of forming a conductive structure provided by examples of the present disclosure;

FIG. 16 is a schematic structure view of forming a semiconductor body provided by examples of the present disclosure;

FIG. 17 is a schematic structure view of a semiconductor structure group illustrated in examples of the present disclosure;

FIG. 18 is a schematic structure view of forming a capacitor structure provided by examples of the present disclosure; and

FIG. 19 is a schematic structure view of a semiconductor device provided by examples of the present disclosure.

In the above drawings (not necessarily drawn to scale), like reference numerals describe like components in different views. Similar reference numerals with different letter suffixes may represent different examples of similar components. The drawings generally illustrate the various examples discussed herein by way of examples rather than limitation.

### DETAILED DESCRIPTION

Example implementations disclosed by the present disclosure will be described below in more details with reference to the drawings. Although the example implementations of the present disclosure are shown in the drawings, it is to be understood that the present disclosure may be implemented in various forms and should not be limited by the specific implementations set forth herein. Rather, these implementations are provided for a more thorough understanding of the present disclosure, and can fully convey a scope disclosed by the present disclosure to those skilled in the art.

In the following description, numerous specific details are given in order to provide a more thorough understanding of the present disclosure. However, it is apparent to those skilled in the art that the present disclosure may be practiced without one or more of these details. In other examples, in order to avoid confusion with the present disclosure, some technical features well-known in the field are not described. That is, all the features of actual examples are not described here, and well-known functions and structures are not described in detail.

In the drawings, sizes of a layer, a region, and an element and their relative sizes may be exaggerated for clarity. Like reference numerals denote like elements throughout the specification.

It should be understood that, spatially relative terms, such as “beneath”, “below”, “lower”, “under”, “over”, “upper”, and the like, may be used herein for ease of description to describe the relationship between one element or feature and other elements or features as illustrated in the figures. It is to be understood that, the spatially relative terms are intended to further encompass different orientations of a device in use or operation in addition to the orientation depicted in the figures. For example, if the device in the drawings is turned over, then the elements or the features described as “below” or “under” or “beneath” other elements may be oriented “on” the other elements or features. Therefore, the example terms “below” and “beneath” may comprise both upper and lower orientations. The device may be orientated otherwise (rotated by 90 degrees or other orientations), and the spatially descriptive terms used herein are interpreted accordingly.

The terms used herein are only intended to describe the specific examples, and are not used as limitations of the present disclosure. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

In order to obtain a more detailed understanding of the characteristics and the technical contents of the examples of the present disclosure, implementation of the examples of the present disclosure is set forth in detail below in conjunction with the drawings, and the appended drawings are only used for reference and illustration, instead of being used to limit the examples of the present disclosure.

The semiconductor device to which the examples of the present disclosure relate is at least a part to be used in subsequent processes to form a final device structure. Here, the final device may include a memory that includes, but is not limited to, a dynamic random access memory. The description is made below by only taking a dynamic random access memory as an example. It is to be noted that, the description below with respect to the dynamic random access memory is only used to illustrate the present disclosure, instead of limiting the scope of the present disclosure.

With the development of dynamic random access memory technology, the size of the memory cell is increasingly smaller, and its array architecture varies from 8F2 to 6F2 and further to 4F2. In addition, based on the requirements for the dynamic random access memory on ions and leakage current, an architecture of the memory evolves from a planar array transistor to a recess gate array transistor, then to a buried channel array transistor, and then to a vertical channel array transistor.

In some examples of the present disclosure, regardless of the planar transistor or the buried transistor, the dynamic random access memory is composed of a plurality of memory cells each being composed of one transistor and one capacitor manipulated by the transistor; that is, the dynamic random access memory includes a (1T1C) architecture of 1 transistor and 1 capacitor. Its main operation principle is to represent whether a binary bit is 1 or 0 according to the amount of charges stored in the capacitor.

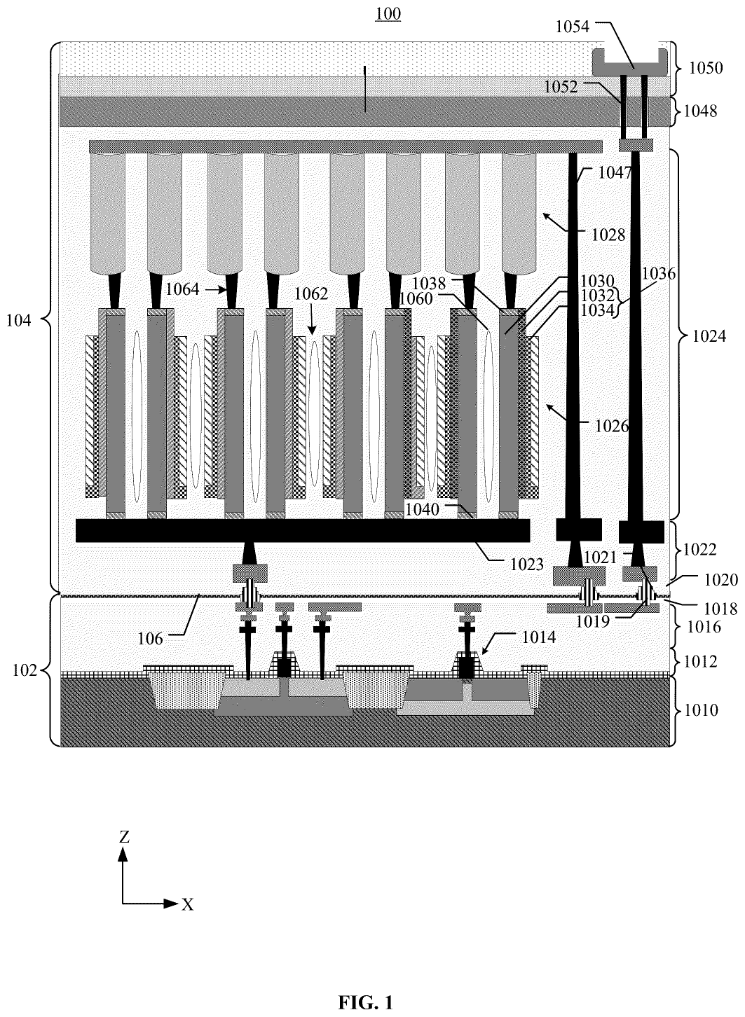

One of the architectures of the dynamic random access memory is described in detail below with reference to FIG. 1. Before introducing a semiconductor device illustrated in FIG. 1, directions that may be used in the following description are defined first. An extending direction of a semiconductor body is defined as a first direction (e.g., a Z direction). A second direction (e.g., an X direction) and a third direction (e.g., a Y direction) that intersect are defined in a plane perpendicular to the Z direction. In some examples, every two of the X direction, the Y direction and the Z direction may be perpendicular to each other.

FIG. 1 is a cross-sectional view of a three-dimensional (3D) dynamic random access memory 100 including a vertical transistor provided in examples of the present disclosure. As shown in FIG. 1, the dynamic random access memory 100 includes a first device 102 and a second device 104 stacked over the first device 102 along a Z-axis direction. The first device 102 and the second device 104 are connected by a bonding interface 106. The first device 102 and the second device 104 may be connected by hybrid bonding or the like. In some examples, the second device 104 may be bonded to the top of the first device 102 in a face-to-face manner at the bonding interface 106.

The first device 102 may include a first substrate 1010, a peripheral circuit 1012 on a side of the first substrate 1010, and a first interconnection layer 1016 on a side of the peripheral circuit 1012 away from the first substrate 1010. The first interconnection layer 1016 is configured to transfer an electrical signal of the peripheral circuit 1012. The peripheral circuit 1012 may include a plurality of transistors 1014. In some examples, a trench isolation (e.g., shallow trench isolation, STI) and a doped region (e.g., a well, a source and a drain of the transistor 1014) may be also formed on or in the first substrate 1010.

The first device 102 may further include a first bonding layer 1018 at the bonding interface 106 and on a side of the first interconnection layer 1016 away from the peripheral circuit 1012. The first bonding layer 1018 may include a plurality of first bonding contacts 1019 and a dielectric that electrically isolates the first bonding contacts 1019. The first bonding contacts 1019 in the first bonding layer 1018 and the surrounding dielectric may be used for hybrid bonding. In contrast, the second device 104 may further include a second bonding layer 1020 at the bonding interface 106 and on a side of the first bonding layer 1018 away from the first interconnection layer 1016. The second bonding layer 1020 may include a plurality of second bonding contacts 1021 and a dielectric that electrically isolates the second bonding contacts 1021. The second bonding contacts 1021 in the second bonding layer 1020 and the surrounding dielectric may be used for hybrid bonding. Here, the second bonding contacts 1021 are in contact with the first bonding contacts 1019 at the bonding interface 106.

In some examples, the peripheral circuit 1012 may further include a word line (WL) and a word line driver/row decoder coupled to a second interconnection layer 1022 through the second bonding contacts 1021 in the second bonding layer 1020 and the first bonding contacts 1019 in the first bonding layer 1018 as well as the first interconnection layer 1016. In some other examples, the peripheral circuit 1012 may further include a bit line 1023 (BL) and a bit line driver/column decoder coupled to the second interconnection layer 1022 through the second bonding contacts 1021 in the second bonding layer 1020 and the first bonding contacts 1019 in the first bonding layer 1018 as well as the first interconnection layer 1016. Here, the second interconnection layer 1022 includes the bit line 1023 above the second bonding layer 1020, and the bit line 1023 is configured to transfer an electrical signal.

In some other examples, the first device 102 and the second device 104 that are stacked may be not connected by bonding, and instead, are integrated on the same substrate (only the first substrate and without the second substrate) and connected directly through one or more interconnection layers between the first device 102 and the second device 104. At this time, the first bonding layer 1018 and the first bonding contacts 1019 are not present in the first device 102; the second bonding layer 1020 and the second bonding contacts 1021 are not present in the second device 104; and the bonding interface 106 between the first device 102 and the second device 104 is not present as well.

With reference to FIG. 1, the second device 104 further includes a memory cell array on the second interconnection layer 1022. The memory cell array may include a plurality of memory cells 1024, a second substrate 1048 on the memory cells 1024, and a third interconnection layer 1050 on the second substrate 1048. The cross section of the dynamic random access memory 100 in FIG. 1 may be taken along a bit line direction (an X-axis direction), and one bit line 1023 in the second interconnection layer 1022 extending laterally in the X-axis direction may be coupled to one column of memory cells 1024.

Here, each memory cell 1024 may include a vertical transistor 1026 and a capacitor structure 1028 coupled to the vertical transistor 1026. The vertical transistor 1026 includes a semiconductor body 1030 extending vertically (in a Z-axis direction), and a gate structure 1036 in contact with one side face of the semiconductor body 1030 in the bit line direction (e.g., the X-axis direction). In some other examples, the gate structure may also completely surround the semiconductor body, half surround the semiconductor body, or be located on two opposite side faces of the semiconductor body, etc., which is not repeated here. Here, the gate structure 1036 includes a gate electrode 1034 and a gate dielectric 1032 between the gate electrode 1034 and the semiconductor body 1030 in the bit line direction (the X-axis direction). In some examples, the gate dielectric 1032 adjoins one side face of the semiconductor body 1030, and the gate electrode 1034 adjoins the gate dielectric 1032.

In some examples, the semiconductor body 1030 has two ends (an upper end and a lower end) in the vertical direction (the Z-axis direction), and one end (e.g., the lower end in FIG. 1) extends beyond the gate dielectric 1032 into an interlayer dielectric (ILD) layer in the vertical direction (the Z-axis direction), while the other end of the semiconductor body 1030 (e.g., the upper end in FIG. 1) is flush with a corresponding end of the gate dielectric 1032. In some other examples, the two ends (the upper end and the lower end) of the semiconductor body 1030 separately extend beyond the gate electrode 1034 into the ILD layer in the vertical direction (the Z-axis direction). In other words, the semiconductor body 1030 may have a greater vertical size than the vertical size (e.g., the depth in the Z-axis direction) of the gate electrode 1034, and neither the upper end nor the lower end of the semiconductor body 1030 is flush with a corresponding end of the gate electrode 1034. As such, a short circuit between the bit line 1023 and the gate electrode 1034 or between the gate electrode 1034 and the capacitor structure 1028 may be avoided.

The vertical transistor 1026 may further include a source 1038 and a drain 1040 disposed at two ends (the upper end and the lower end) of the semiconductor body 1030 respectively in the vertical direction (the Z-axis direction). The positions of the source and the drain may be interchanged, and as an example here and hereinafter, the upper end is the source 1038 and the lower end is the drain 1040. In some implementations, the source 1038 is coupled to the capacitor structure 1028, and the drain 1040 is coupled to the bit line 1023.

Since the gate electrode 1034 may be a part of the word line or extend as the word line in a word line direction, the second device 104 of the dynamic random access memory 100 may also include a plurality of word lines each extending in the word line direction (the Y-axis direction). Here, each word line may be coupled to one row of memory cells 1024.

The vertical transistor 1026 extends vertically through the word line and is in contact with the word line, and the drain 1040 at the lower end of the vertical transistor 1026 is in contact with the bit line 1023. Therefore, due to the vertical arrangement of the vertical transistor 1026, the word line and the bit line 1023 can be disposed in different planes in the vertical direction, which simplifies the routing of the word line and the bit line 1023. Here, the vertical transistor 1026 may be arranged in a mirror-symmetrical manner so as to increase the density of the memory cells 1024 in the bit line direction (the X-axis direction). Two adjacent ones of the vertical transistors 1026 in the bit line direction are mirror-symmetrical to each other with respect to a trench isolation 1060. That is to say, the second device 104 may include a plurality of trench isolations 1060, where each trench isolation 1060 and the word line extend in parallel in the word line direction (the Y-axis direction), and are disposed between two adjacent rows of semiconductor bodies 1030 of the vertical transistor 1026. In some implementations, the rows of vertical transistors 1026 separated by the trench isolation 1060 are mirror-symmetrical to each other with respect to the trench isolation 1060. It should be understood that the trench isolation 1060 may include air gaps each laterally disposed between adjacent ones of the semiconductor bodies 1030. The second device 104 may further include a plurality of gate isolations 1062, where each gate isolation 1062 and the word line extend in parallel in the word line direction (the Y-axis direction), and are disposed between two adjacent rows of word lines of the vertical transistor 1026. It should be understood that the sizes of the gate isolation 1062 and the word line in the bit line direction (the X-axis direction) may be the same as or different from the size of the trench isolation 1060 in the bit line direction (the X-axis direction). When the sizes of them in the bit line direction (the X-axis direction) are different, spacings between a plurality of semiconductor bodies 1030 arranged along the bit line direction (the X-axis direction) are different. e.g., the plurality of semiconductor bodies 1030 arranged along the bit line direction (the X-axis direction) are arranged non-uniformly.

As shown in FIG. 1, the capacitor structure 1028 may be a vertical capacitor. In some implementations, a conductive structure 1064 is formed between the vertical transistor 1026 (further, e.g., the source 1038) and the capacitor structure 1028 to reduce the contact resistance.

As shown in FIG. 1, the second device 104 may further include a capacitor contact 1047 in contact with a common plate of the capacitor structure 1028 to couple the capacitor structure 1028 to the peripheral circuit 1012 or directly couple it to the ground. In some implementations, the ILD layer that forms the capacitor structure 1028 includes the same dielectric material as the two ILD layers into which the semiconductor bodies 1030 extend, e.g., silicon oxide. A configuration of the capacitor structure 1028 may include any suitable structure and configuration, e.g., a planar capacitor, a stack capacitor, a multi-fin capacitor, a cylinder capacitor, a trench capacitor or a substrate-plate capacitor.

As shown in FIG. 1, the vertical transistor 1026 extends vertically through the word line and is in contact with the word line. The drain 1040 at the lower end of the vertical transistor 1026 is in contact with the bit line 1023, and the source 1038 at the upper end of the vertical transistor 1026 is in contact with the capacitor structure 1028. That is, due to the vertical arrangement of the vertical transistor 1026, the bit line 1023 and the capacitor structure 1028 can be disposed in different planes in the vertical direction, and coupled to opposite ends of the vertical transistor 1026 of the memory cell 1024 in the vertical direction. In some implementations, the bit line 1023 and the capacitor structure 1028 are disposed on opposite side faces of the vertical transistor 1026 in the vertical direction, which simplifies the routing of the bit line 1023 and reduces coupling capacitance between the bit line 1023 and the capacitor structure 1028, compared with a conventional memory cell where a bit line and a capacitor structure are disposed on the same side face of a planar transistor.

In some examples, the vertical transistor 1026 is disposed vertically between the capacitor structure 1028 and the bonding interface 106. That is, the vertical transistor 1026 may be arranged closer to the peripheral circuit 1012/bonding interface 106 of the first device 102 than the capacitor structure 1028. Since the bit line 1023 and the capacitor structure 1028 are coupled to the opposite ends of the vertical transistor 1026, the bit line 1023, which serves as part of the second interconnection layer 1022, is disposed vertically between the vertical transistor 1026 and the bonding interface 106 to reduce a routing distance and the complexity of interconnection.

In some examples, the second device 104 further includes a second substrate 1048 disposed above the memory cell 1024, and a pad-out third interconnection layer 1050 above the memory cell 1024. The pad-out third interconnection layer 1050 may include an interconnection in one or more ILD layers, e.g., a contact pad 1054.

In some examples, the second device 104 further includes one or more contacts 1052 that extend through the pad-out third interconnection layer 1050 and the second substrate 1048 to pass through the pad-out third interconnection layer 1050 and be coupled to the memory cell 1024 and the second interconnection layer 1022. As such, the peripheral circuit 1012 can be coupled to the memory cell 1024 through the first interconnection layer 1016 and the second interconnection layer 1022 as well as the second bonding layer 1020 and the first bonding layer 1018, and the peripheral circuit 1012 and the memory cell 1024 can be led out to the third interconnection layer 1050 through the contacts 1052 and pads and be coupled to an external circuit.

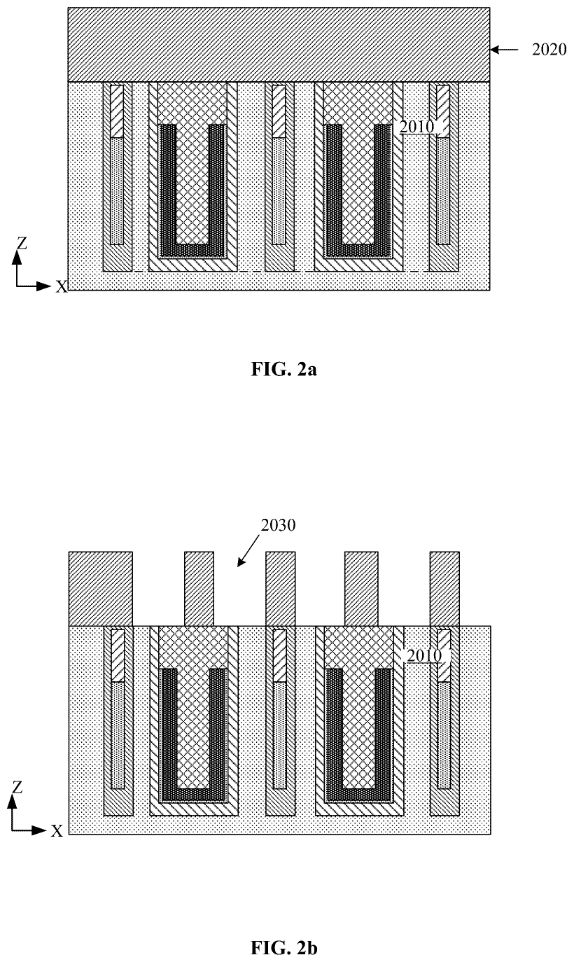

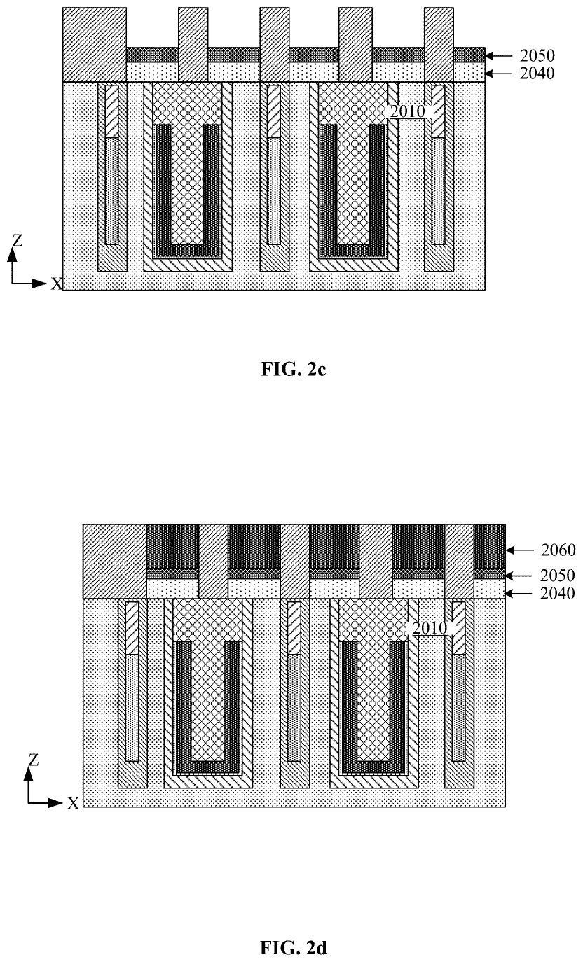

As described previously, to reduce the contact resistance between the source 1038 and the capacitor structure 1028, the conductive structure 1064 is disposed between the source 1038 and the capacitor structure 1028. The examples of the present disclosure provide a method of fabricating a conductive structure 1064 with reference to FIGS. 2a to 2d.

As shown in FIG. 2a, a mask layer 2020 is formed on the semiconductor pillar 2010.

As shown in FIG. 2b, a conductive hole 2030 is formed in the mask layer 2020 using a self-alignment technique to expose an upper end of the semiconductor pillar 2010.

As shown in FIG. 2c, a polysilicon layer 2040 is deposited in the conductive hole 2030, and the polysilicon is etched back (EB), and a metal silicide layer 2050, e.g., cobalt silicide (CoSi), is formed on the remaining polysilicon layer. The polysilicon layer 2040 is connected with the upper end of the semiconductor pillar 2010.

As shown in FIG. 2d, a conductive layer 2060 (such as titanium nitride (TiN), tungsten (W), etc.) is formed in the conductive hole 2030 and on the metal silicide layer 2050, and chemical mechanical polishing (CMP) is performed on the conductive layer 2060 to form the conductive structure 1064.

However, as the size of the semiconductor device gradually decreases, there are many problems to overcome when adopting the self-alignment technique, such as non-uniformity of arrangement of the semiconductor bodies, a depth difference between the semiconductor body and the word line in the Z-axis direction, the complexity of the self-alignment technique, technical defects in a process of forming the metal silicide layer, etc., which results in increased alignment difficulty between the conductive structure and the semiconductor body and between the conductive structure and the capacitor structure and easily causes current leakage between the conductive structure and the word line, and a possible increased manufacturing cost and the like.

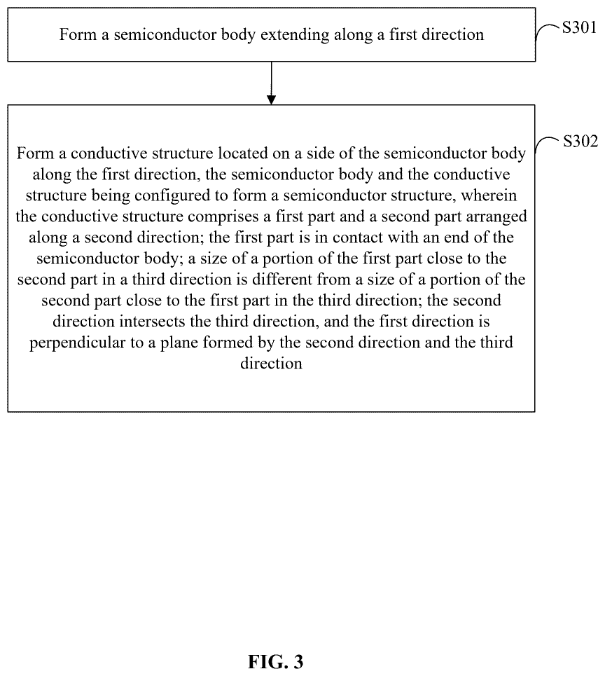

On this basis, in order to solve one or more of the above problems, the examples of the present disclosure further provide a manufacturing method of a semiconductor device. FIG. 3 is a flow diagram of a manufacturing method of a semiconductor device provided by examples of the present disclosure. The manufacturing method includes:

Operation S301: forming a semiconductor body extending along a first direction; and

Operation S302: forming a conductive structure located on a side of the semiconductor body along the first direction, the semiconductor body and the conductive structure being configured to form a semiconductor structure, where the conductive structure includes a first part and a second part arranged along a second direction; the first part is in contact with an end of the semiconductor body; a size of a portion of the first part close to the second part in a third direction is different from a size of a portion of the second part close to the first part in the third direction; the second direction intersects the third direction, and the first direction is perpendicular to a plane formed by the second direction and the third direction.

It should be understood that the operations as illustrated in FIG. 3 are not exclusive, and other operations may be also performed before, after, or between any of the illustrated operations. A sequence of the operations illustrated in FIG. 3 can be adjusted according to actual needs. It should be noted that the semiconductor device may include one or more semiconductor structures. As an example here and hereinafter, the semiconductor device includes a plurality of semiconductor structures.

It should be understood that the semiconductor structure are formed in different ways when the gate structure and the semiconductor body in the semiconductor structure have different relative positions. In the examples of the present disclosure, the gate structures of two adjacent ones of the semiconductor structures are disposed in a face-to-face manner. However, it should be understood that the following description about the relative position of the gate structure and the semiconductor body is only for illustrating the present disclosure rather than limiting the scope of the present disclosure. On this basis, the semiconductor device described in the examples of the present disclosure may include a plurality of semiconductor structures arranged in an array along the X-axis direction and the Y-axis direction. The plurality of semiconductor structures arranged along the X-axis direction include a first semiconductor structure and a second semiconductor structure arranged alternately. The first semiconductor structure and the second semiconductor structure disposed adjacently constitute one semiconductor structure group.

A formation process of the plurality of semiconductor structures are described in detail below in conjunction with the drawings.

In some examples, the operation S301 is performed, and the manufacturing method includes: providing a semiconductor layer, and in the semiconductor layer, forming a plurality of first grooves extending along the second direction and spaced apart along the third direction, and a plurality of second grooves and a plurality of third grooves extending along the third direction and alternately spaced apart along the second direction, to form a plurality of semiconductor pillars arranged in an array along the first direction and the second direction; forming a first isolation structure in the second groove; forming a gate material layer in the third groove, where the gate material layer covers part of a surface of the semiconductor pillar and covers an exposed bottom surface of the semiconductor layer; and forming a first sub-structure on a side of the gate material layer away from the semiconductor pillar along the second direction.

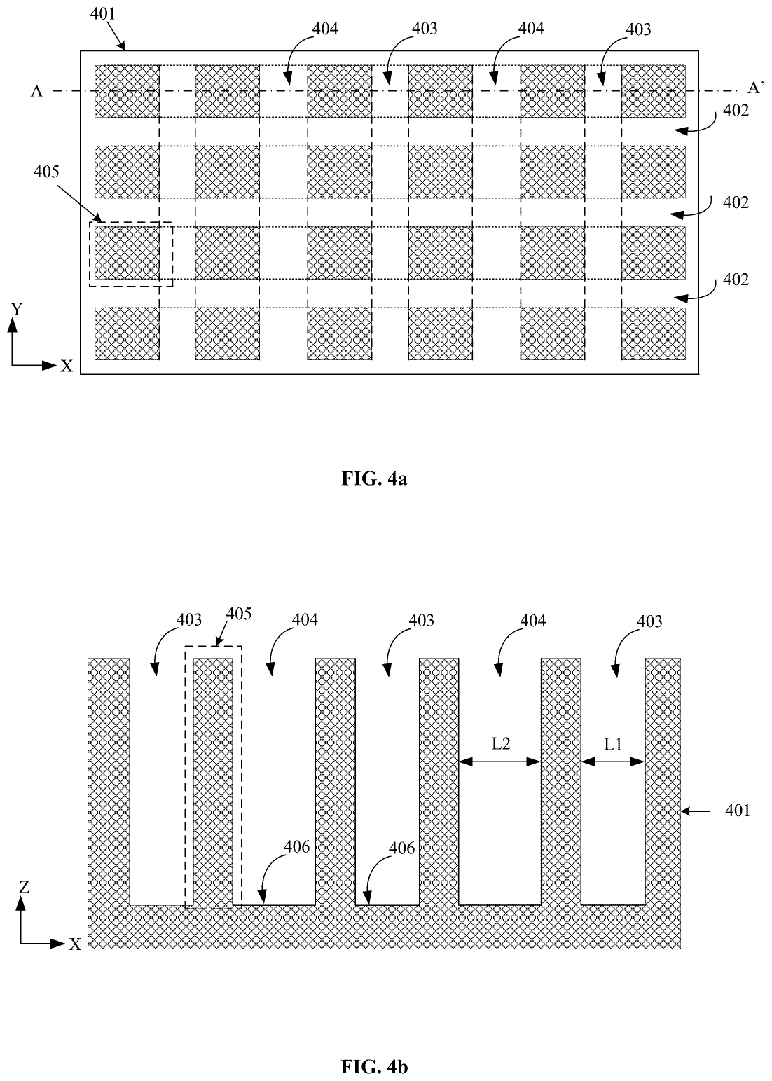

With reference to FIGS. 4a and 4b, FIG. 4b is a cross-sectional schematic view of FIG. 4a along a direction AA′. A semiconductor layer 401 is provided, and in the semiconductor layer 401, a plurality of first grooves 402 extending along the X-axis direction and spaced apart along the Y-axis direction are formed, and a plurality of second grooves 403 and a plurality of third grooves 404 extending along the Y-axis direction and alternately spaced apart along the X-axis direction are formed. The plurality of first grooves 402, the plurality of second grooves 403 and the plurality of third grooves 404 divide part of the semiconductor layer 401 into a plurality of semiconductor pillars 405 arranged in an array (as shown by a dashed box in FIG. 4a), thereby exposing the bottom surface 406 of the semiconductor layer. A composition material of the semiconductor layer 401 includes, but is not limited to silicon (Si).

The size of the second groove 403 along the X-axis direction may be the same as or may be different from the size of the third groove 404 along the X-axis direction. In consideration of different structures formed in the second groove 403 and the third groove 404 in the subsequent process and efficient utilization of the area of the semiconductor layer, here, the size of the third groove 404 along the X-axis direction is set to be greater than the size of the second groove 403 along the X-axis direction. In an example, with reference to FIG. 4b, the size of the second groove 403 along the X-axis direction is L1 and the size of the third groove 404 along the X-axis direction is L2, and here, L2>L1. In other words, the plurality of semiconductor pillars are arranged non-uniformly.

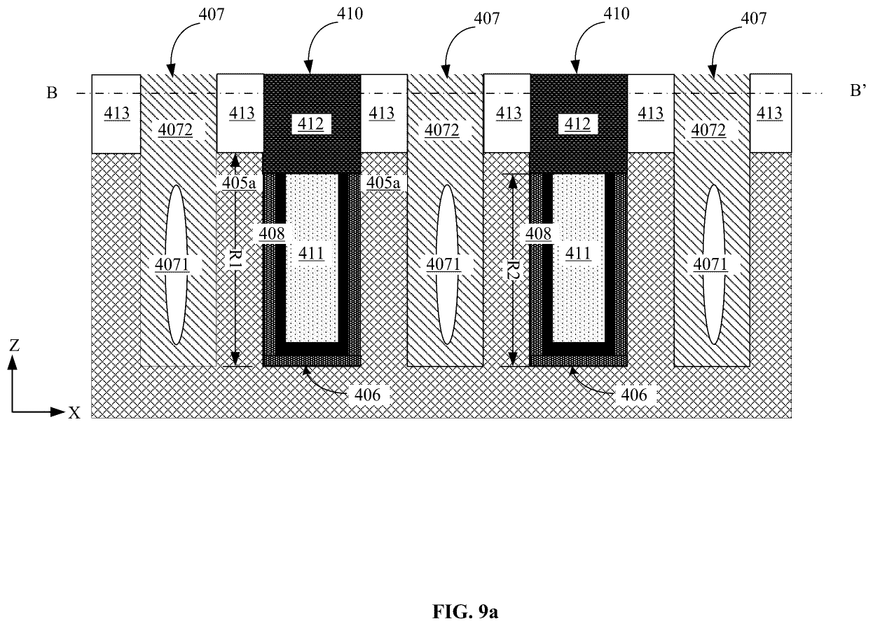

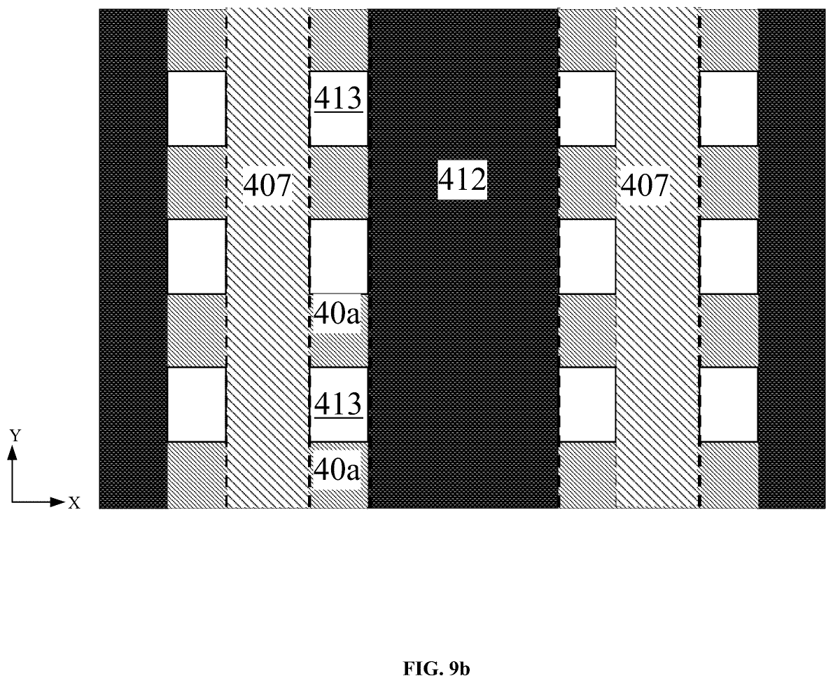

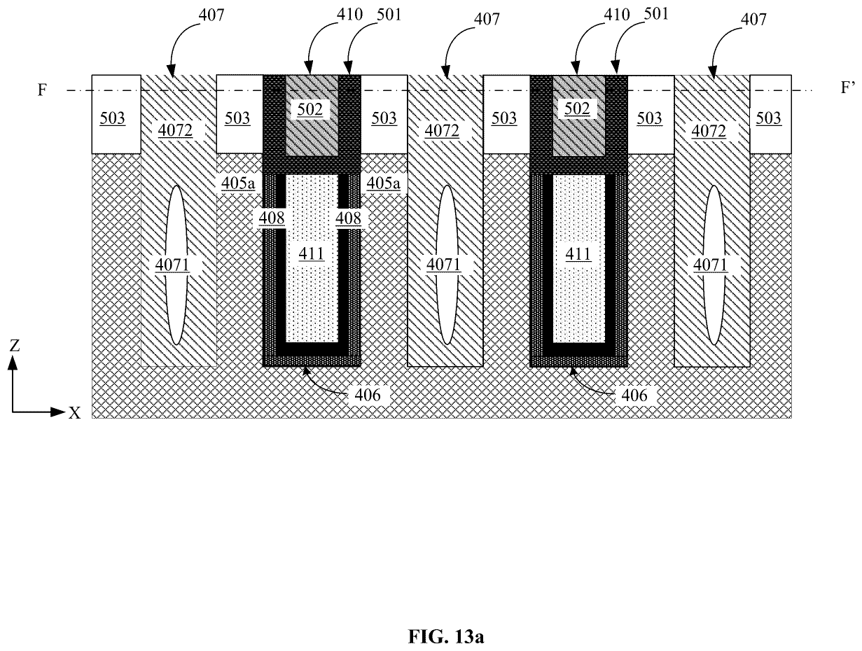

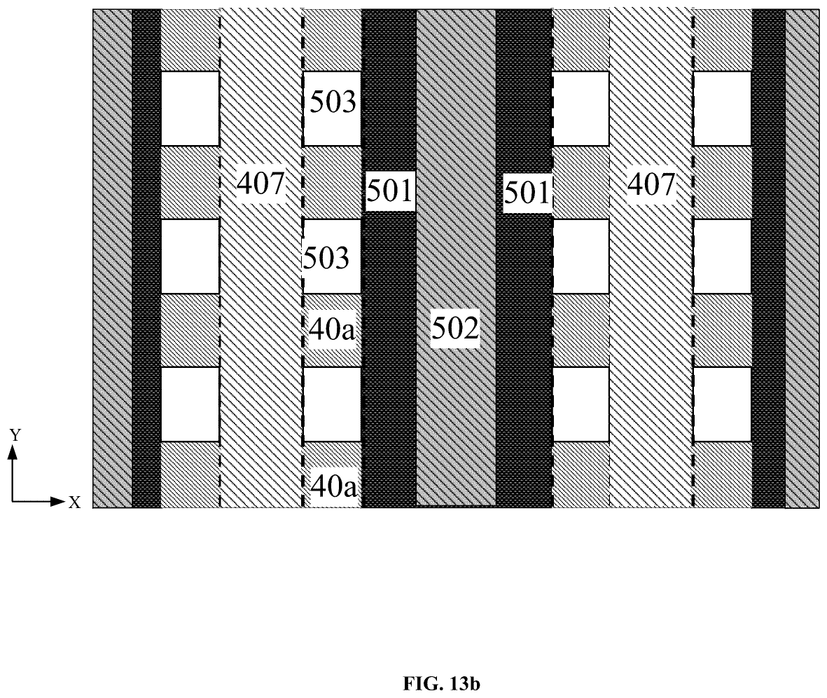

In some examples, the first groove 402, the second groove 403, and the third groove 404 may be formed by a lithography process (which may be referred to as lithography-etch here and hereinafter). A sequence of forming the first groove 402, the second groove 403, and the third groove 404 may be selected according to actual requirements. In an example, the first groove 402 is formed first and then the second groove 403 and the third groove 404 are formed. The manufacturing method may include: forming a first mask layer on a surface of the semiconductor layer 401; developing and exposing the first mask layer to form a first preset pattern corresponding to the first groove; forming the first groove 402 using the first mask layer and the first preset pattern; and then filling the first groove 402 with an insulation material (labelled as 40a in FIGS. 9b and 13b), such as silicon oxide (SiO₂), and removing the first mask layer. Next, a second mask layer is formed on the surface of the semiconductor layer 401, where the second mask layer is further configured to cover a top surface of the insulation material. The second mask layer are developed and exposed to form a second preset pattern corresponding to the second groove and the third groove. Based on the second mask layer and the second preset pattern, the second groove 403 and the third groove 404 are formed and the second mask layer is removed. Methods of forming the first groove, the second groove and the third groove may also include other methods, which will be no longer described in the present disclosure. A method of filling the first groove with the insulation material includes, but is not limited to, physical vapor deposition (PVD), chemical vapor deposition (CVD), atomic layer deposition (ALD) and the like.

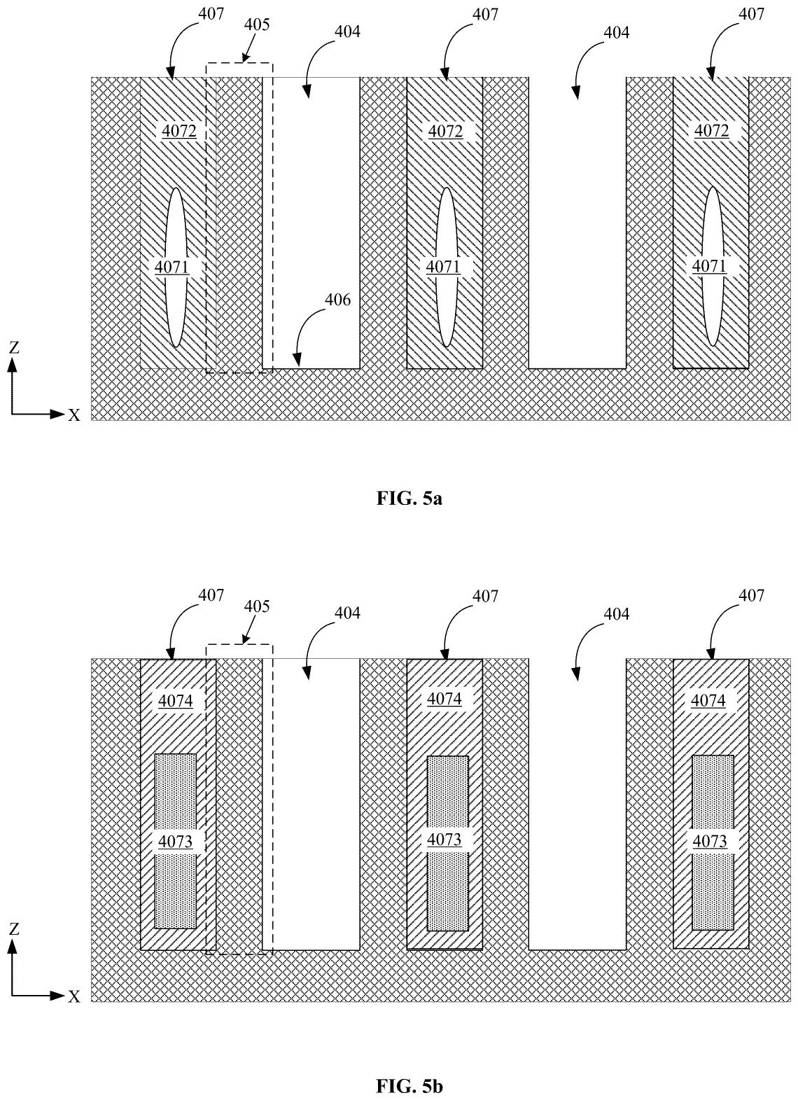

A first isolation structure 407 is formed in the second groove 403. The first isolation structure 407 may be used to reduce a coupling capacitance between two adjacent semiconductor devices. The first isolation structure 407 may include an air gap 4071 and a cap layer 4072 (with reference to FIG. 5a), and may also include a conductive material layer 4073 and a protection layer 4074 (with reference to FIG. 5b). However, it should be noted that when the first isolation structure includes the conductive material layer, the conductive material layer needs to be surrounded by the protection layer to avoid the conductive material layer from contacting with the semiconductor pillar. The air gap 4071 may include air. A composition material of the cap layer 4072 includes, but is not limited to, silicon oxide. A composition material of the conductive material layer 4073 includes, but is not limited to, tungsten (W). A composition material of the protection layer 4074 includes, but is not limited to, silicon. A method of forming the first isolation structure 407 includes, but is not limited to, PVD, CVD, ALD, and the like.

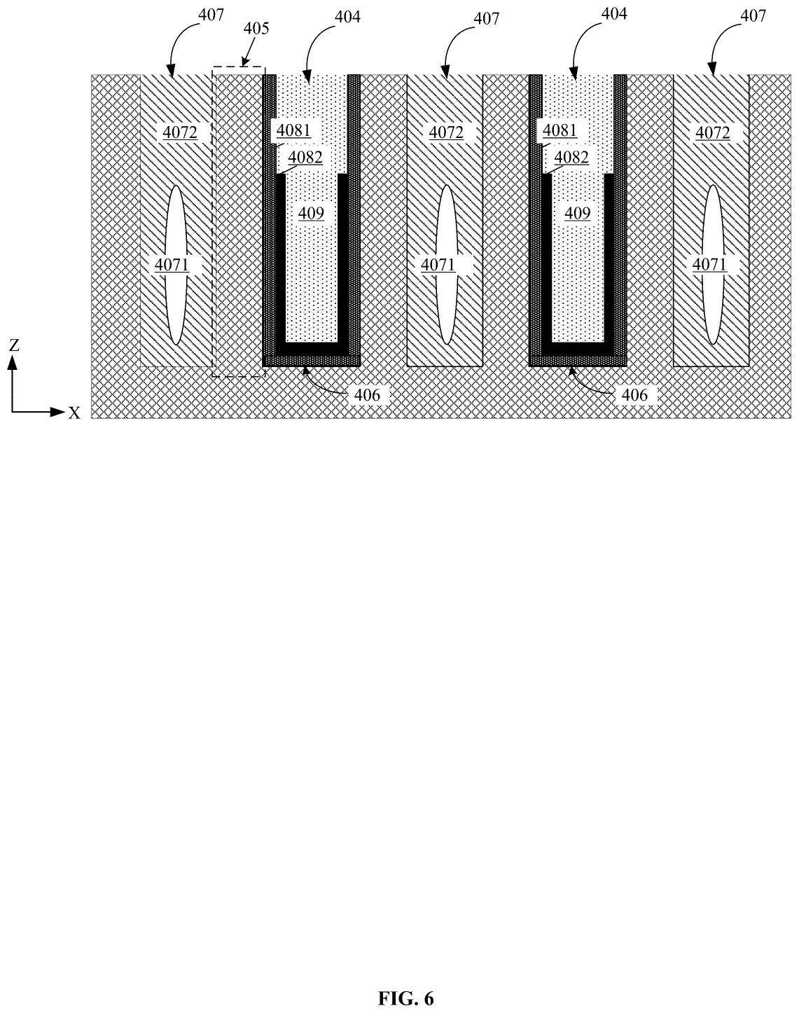

With reference to FIG. 6, a dielectric material layer 4081 covering a sidewall of the third groove 404 (e.g., a surface of a semiconductor pillar 405) and a bottom of the third groove 404 (e.g., the bottom surface 406 of the semiconductor layer) is formed in the third groove 404, and a gate layer 4082 covering a surface of part of the dielectric material layer 4081 is formed. A composition material of the dielectric material layer 4081 includes, but is not limited to, silicon oxide, and a composition material of the gate layer 4082 includes, but is not limited to, a metal (e.g., tungsten (W)). A method of forming the dielectric material layer 4081 and the gate layer 4082 includes, but is not limited to, PVD, CVD, ALD, and the like.

With continued reference to FIG. 6, the third groove 404 is filled with an insulation material layer 409. A composition material of the insulation material layer 409 includes, but is not limited to, silicon oxide. A method of forming the insulation material layer 409 includes, but is not limited to, PVD, CVD, ALD, and the like.

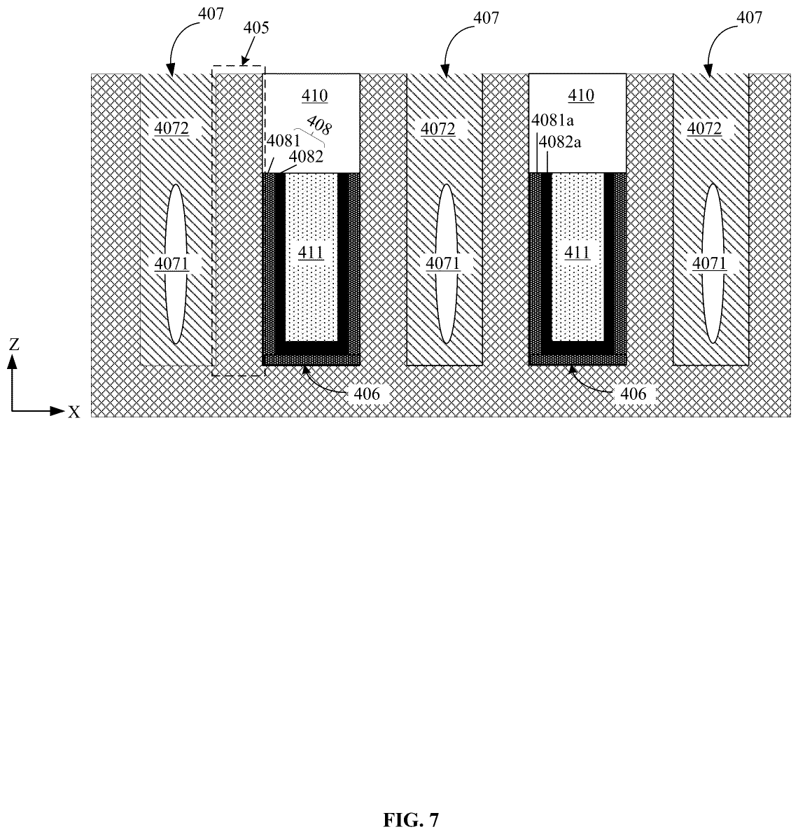

With reference to FIG. 7, part of the dielectric material layer 4081 and part of the insulation material layer 409 are removed to form a first trench 410. It should be understood that the first trench 410 is a part of the third groove 404. The remaining dielectric material layer 4081 and the gate layer 4082 constitute a gate material layer 408, and the remaining insulation material layer 409 constitutes a first sub-structure 411. The removing process includes, but is not limited to, dry etching and the like. It should be understood that the first sub-structure 411 is located on a side of the gate material layer 408 away from the semiconductor pillar 405 along the X-axis direction. Here, a top surface of the remaining dielectric material layer 4081 and a top surface of the gate layer 4082 may be aligned or not aligned along the X-axis direction. As shown in FIG. 7, the top surface 4081a of the remaining dielectric material layer 4081 and the top surface 4082a of the gate layer 4082 are aligned along the X-axis direction.

The operation S302 is performed to form a conductive structure, which includes forming a conductive hole and forming the conductive structure in the conductive hole. It needs to be noted that there may be multiple methods of forming the conductive hole and the conductive structure, and two example methods are illustrated in the examples of the present disclosure, which are described in detail below in conjunction with the drawings.

### Method I:

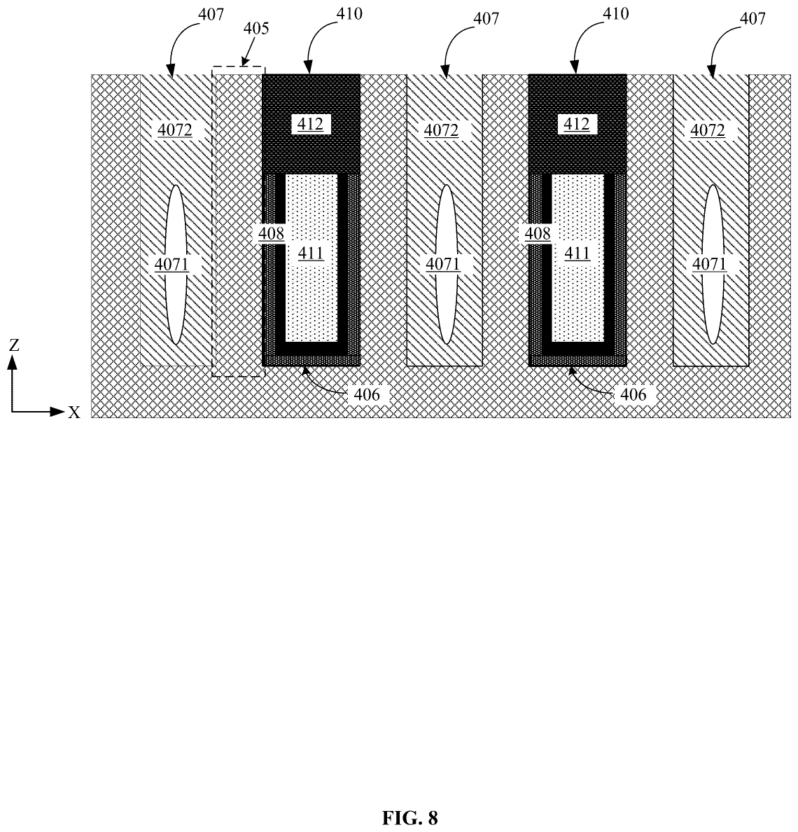

With reference to FIG. 8, the method includes: filling the first trench 410 with a first dielectric layer 412. At this time, the first dielectric layer 412 is located on a side of the semiconductor pillar 405 away from the first isolation structure 407, and the first dielectric layer 412 covers the remaining surface of the semiconductor pillar 405. It should be understood that the first dielectric layer 412 is located on a side of the gate material layer 408 and the first sub-structure 411 away from the bottom surface 406 of the semiconductor layer along the Z-axis direction, and covers surfaces of the gate material layer 408 and the first sub-structure 411 away from the bottom surface 406 of the semiconductor layer along the Z-axis direction. A composition material of the first dielectric layer 412 includes, but is not limited to, silicon nitride (SiN). A method of forming the first dielectric layer 412 includes, but is not limited to, PVD, CVD, ALD, and the like.

In some examples, based on a certain etchant, such as hot phosphoric acid, an etching rate of the first dielectric layer 412 is greater than an etching rate of the insulation material 40a, the etching rate of the first dielectric layer 412 is greater than an etching rate of the first isolation structure 407, and the etching rate of the first dielectric layer 412 is greater than an etching rate of the semiconductor pillar 405. In other words, based on a certain etchant, such as hot phosphoric acid, it is easier to remove the first dielectric layer 412 than to remove the insulation material 40a (with reference to 40a shown in FIG. 9b), the first isolation structure 407 and the semiconductor pillar 405.

With reference to FIGS. 9a and 9b, FIG. 9b is a cross-sectional schematic view of FIG. 9a along a direction BB′. The method further includes: removing part of the semiconductor pillar to form a fourth groove 413. The removing process includes, but is not limited to, dry etching. The size of the remaining semiconductor pillar 405a along the Z-axis direction is greater than the size of the gate material layer 408 along the Z-axis direction. As shown in FIG. 9a, the size of the remaining semiconductor pillar 405a along the Z-axis direction is R1 and the size of the gate material layer 408 along the Z-axis direction is R2, and here, R1>R2.

In some examples, with reference to FIG. 9a, a sidewall (e.g., a surface) of the fourth groove 413 away from the first dielectric layer 412 in the X-axis direction is aligned with a surface of the remaining semiconductor pillar 405a away from the gate material layer 408 in the X-axis direction along the Z-axis direction.

With reference to FIG. 9b, the fourth groove 413 has one surface along the X-axis direction adjacent to the first isolation structure 407 and another surface along the X-axis direction adjacent to the first dielectric layer 412. Two opposite sides of the fourth groove 413 along the Y-axis direction are adjacent to the insulation material 40a that is filled in the first groove.

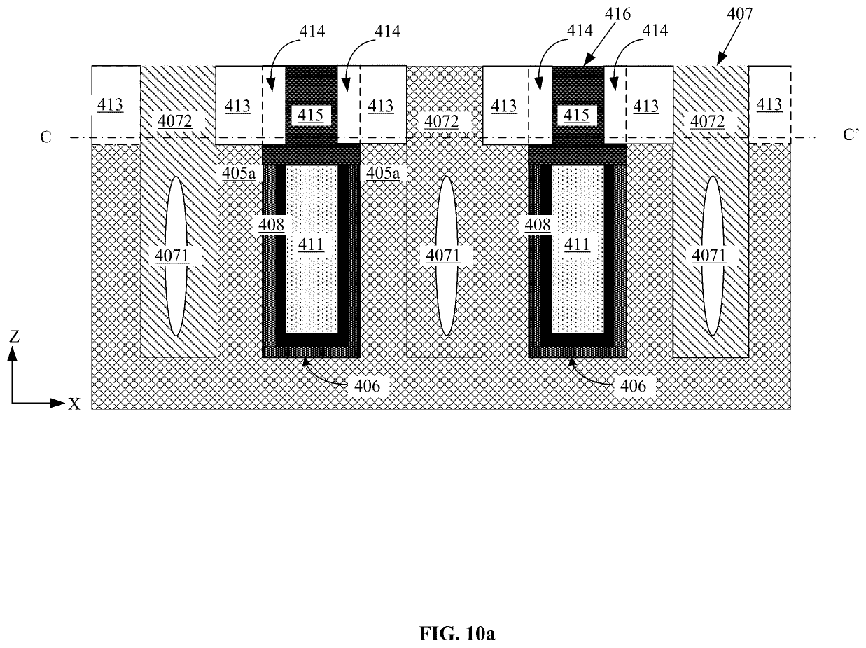

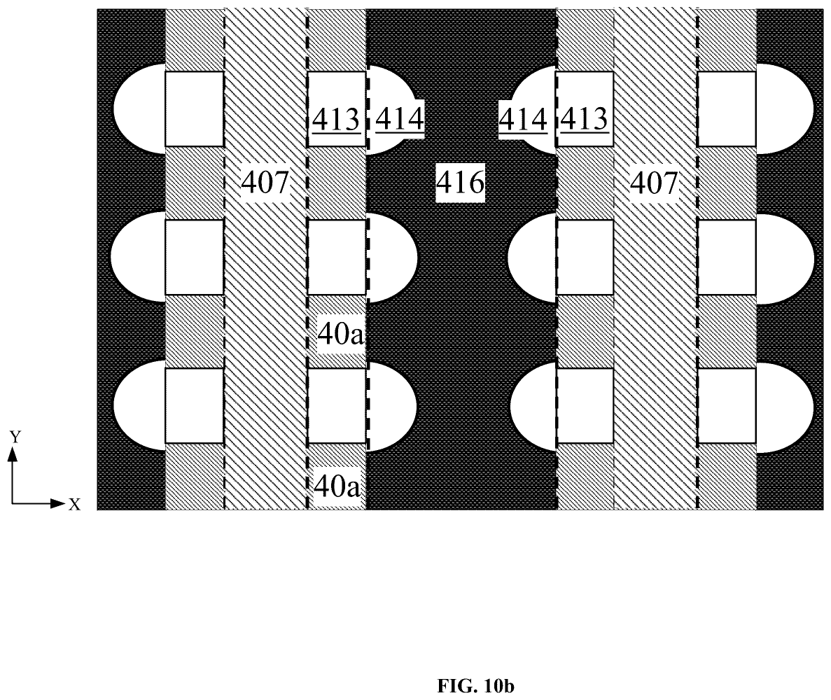

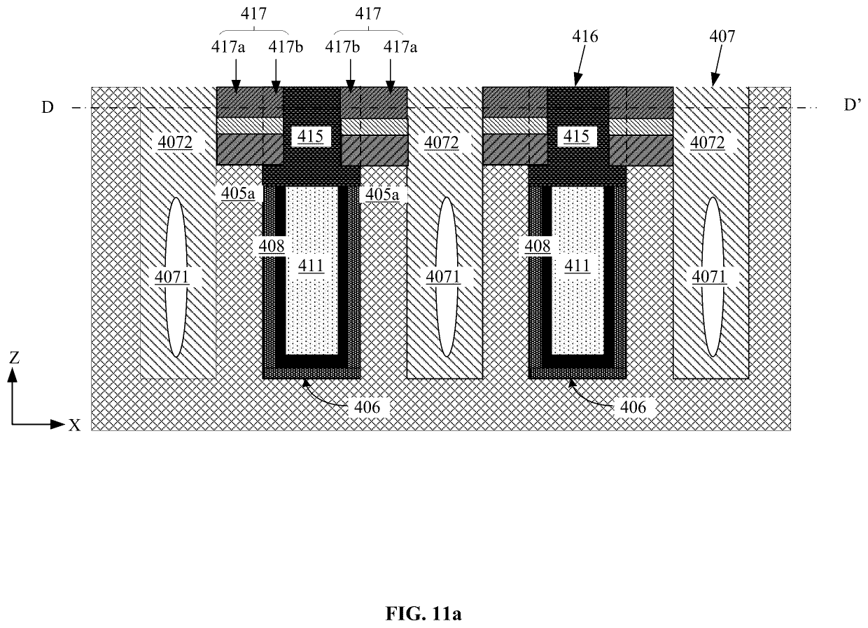

In some examples, with reference to FIG. 10a, part of the first dielectric layer 412 is removed to form a fifth groove 414 having a curved edge. The fourth groove 413 and the fifth groove 414 together constitute a conductive hole. The remaining first dielectric layer 412 constitutes a second sub-structure 415. Here, the first sub-structure 411 and the second sub-structure 415 together constitute a second isolation structure 416.

A method for removing part of the first dielectric layer 412 includes, but is not limited to, wet etching. In an example, the fourth groove 413 is filled with an etchant, such as hot phosphoric acid, and the first dielectric layer 412 is etched by the etchant to remove part of the first dielectric layer 412. It should be understood that the amount of the removed first dielectric layer is related to composition of the etchant, concentration of the etchant, and etching temperature, etc., which is not specified in detail in the present disclosure. However, it should be understood that based on an isotropic etching characteristic of wet etching, the formed fifth groove 414 has a curved edge. In other words, a cross-sectional shape of the fifth groove 414 in an XY-plane includes an axisymmetric shape having a curved edge.

In some examples, with reference to FIG. 10b, FIG. 10b is a cross-sectional schematic view of FIG. 10a along a direction CC′. A cross-sectional shape of the fourth groove 413 in the XY-plane includes a rectangle, such as a square, an oblong, etc. A cross-sectional shape of the fifth groove 414 in the XY-plane includes an irregular semicircle.

Since the etchant may slightly etch the structure (e.g., the first isolation structure 407, the insulation material 40a, and the remaining semiconductor pillar 405a) surrounding the fourth groove; in other words, a boundary of the fourth groove may expand outwards after the fifth groove is formed by wet etching, an interface shape of the fourth groove in the XY-plane is presented as an irregular rectangular shape. However, since the amount of the structure (e.g., the first isolation structure 407 and the insulation material 40a) surrounding the fourth groove etched by the etchant is small, the size of the expansion of the boundary of the fourth groove is small. In an example, a small amount of the first isolation structure is removed by the etchant, and at this time, a sidewall of the fourth groove 413 close to the first isolation structure 407 in the X-axis direction is not aligned with a side surface of the remaining semiconductor pillar 405a away from the gate material layer 408 along the Z-axis direction. In an example, a spacing of a surface of the fourth groove 413 close to the first isolation structure 407 in the X-axis direction and the surface of the remaining semiconductor pillar 405a away from the gate material layer 408 in the X-axis direction is less than a preset value. In an example, the preset value is less than 3 nm. However, it should be understood that the amount of the structure surrounding the fourth groove etched by the etchant is small. As such, the size of the outward expansion of the fourth groove is relatively small, which will not affect the formation of the conductive structure in the subsequent process and also will not affect the performance of the conductive structure. Therefore, the size of the outward expansion of the fourth groove is neglected in the present disclosure.

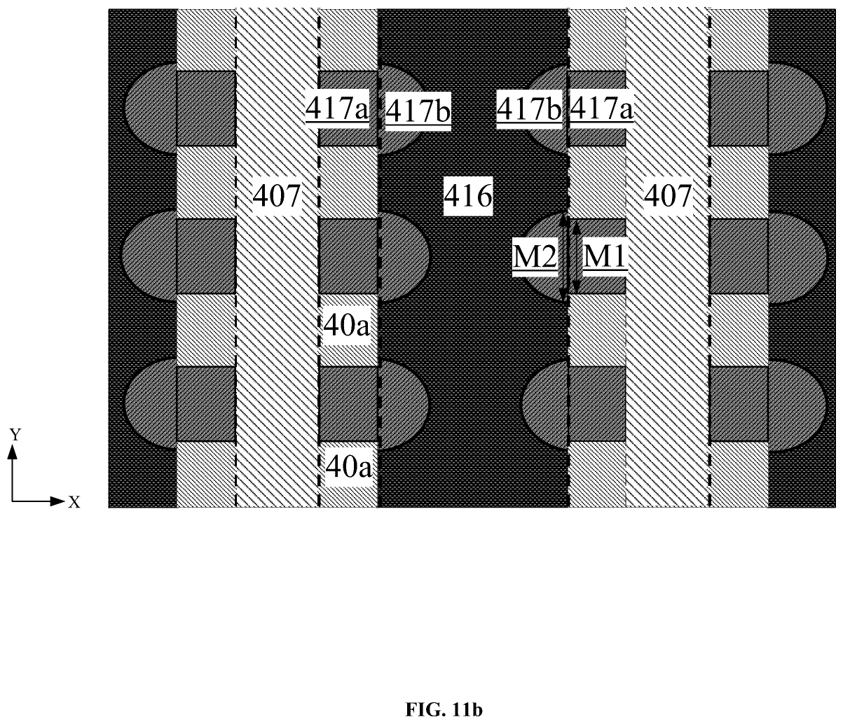

In some examples, with reference to FIG. 11a, the method further includes: forming a first part 417a of the conductive structure 417 in the fourth groove and forming a second part 417b of the conductive structure 417 in the fifth groove, where the first part 417a of the conductive structure is in contact with an end of the remaining semiconductor pillar 405a.

In some examples, a size of a portion of the first part 417a of the conductive structure close to the second part 417b of the conductive structure in the Y-axis direction is different from a size of a portion of the second part 417b of the conductive structure close to the first part 417a of the conductive structure in the Y-axis direction.

In an example, FIG. 11b is a cross-sectional schematic view of FIG. 11a along a direction DD′, the size of the portion of the first part 417a of the conductive structure close to the second part 417b of the conductive structure in the Y-axis direction is a first size M1, and the size of the portion of the second part 417b of the conductive structure close to the first part 417a of the conductive structure in the Y-axis direction is a second size M2. The second size M2 is greater than the first size M1, e.g., M2>M1.

In some examples, the first isolation structure includes a first end face and a second end face that are opposite along the first direction, and the second isolation structure includes a third end face and a fourth end face that are opposite along the first direction. The first end face, the third end face, a surface of the first part of the conductive structure away from the semiconductor body along the first direction, and a surface of the second part of the conductive structure away from the gate structure along the first direction are aligned along the second direction.

In an example, with reference to FIG. 11a, a surface of the first isolation structure 407 away from the bottom surface 406 of the semiconductor layer along the Z-axis direction (e.g., the first end face, e.g., a top surface of the first isolation structure 407), a surface of the second isolation structure 416 away from the bottom surface 406 of the semiconductor layer along the Z-axis direction (e.g., the third end face, e.g., a top surface of the second isolation structure 416), a surface of the first part 417a of the conductive structure away from the bottom surface 406 of the semiconductor layer along the Z-axis direction (e.g., a top surface of the first part 417a of the conductive structure), and a surface of the second part 417b of the conductive structure away from the gate material layer along the Z-axis direction (e.g., a top surface of the second part 417b of the conductive structure) are aligned along the X-axis direction.

Since the size of the remaining semiconductor pillar 405a along the Z-axis direction is greater than the size of the gate material layer 408 along the Z-axis direction, the conductive structure 417 and the gate material layer 408 are spaced apart. As shown in FIG. 11a, the conductive structure 417 and the gate material layer 408 are spaced apart by the second sub-structure 415. As such, current leakage between the gate material layer 408 (which is subsequently formed into a gate structure) and the conductive structure 417 may be avoided, thereby improving the reliability of the semiconductor device.

In some examples, the conductive structure may include a polysilicon layer, a metal silicide layer and a conductive metal layer stacked along the Z-axis direction, where the polysilicon layer is in contact with the semiconductor body; or the conductive structure may include a polysilicon layer and a metal silicide layer stacked along the Z-axis direction, where the polysilicon layer is in contact with the semiconductor body; or the conductive structure may include a metal silicide layer in contact with the semiconductor body.

In other words, in some examples, a method of forming the conductive structure may include: forming a polysilicon layer (e.g., Poly) in the fourth groove and the fifth groove, where the polysilicon layer is in contact with an end of the remaining semiconductor pillar; forming a metal silicide layer (silicide, such as CoSi) on a side of the polysilicon layer away from the remaining semiconductor pillar; and forming a conductive metal layer (e.g., TiN and W) on a side of the metal silicide layer away from the polysilicon layer.

In some examples, a method of forming the conductive structure may include: forming a polysilicon layer in the fourth groove and the fifth groove, where the polysilicon layer is in contact with an end of the remaining semiconductor pillar; and forming a metal silicide layer on a side of the polysilicon layer away from the remaining semiconductor pillar.

In some examples, a method of forming the conductive structure may include: forming a polysilicon layer in the fourth groove and the fifth groove; and metallizing the polysilicon layer to obtain a metal silicide, to form the conductive structure.

The method of forming the metal silicide layer in the above examples may include metallizing part of the polysilicon layer or depositing the metal silicide layer on the polysilicon layer, which will not be specified in detail in the present disclosure. The method of forming the polysilicon layer and the conductive metal layer may include, but is not limited to, PVD, CVD, ALD, and the like.

In the examples of the present disclosure, part of the semiconductor pillar is removed to form the fourth groove, and the first part of the conductive structure in direct contact with the remaining semiconductor pillar is formed in the fourth groove. As such, the alignment accuracy of the first part of the conductive structure and the remaining semiconductor pillar can be increased, which in turn reduces the alignment difficulty of them and improves the reliability of the semiconductor device. In addition, by the expansion of the fourth groove, the fifth groove is formed, so that the size of the conductive hole can be increased, which in turns increases the top surface of the conductive structure. As such, the contact area of the conductive structure and other device structure (e.g., the capacitor structure) is increased, and the process difficulty of achieving the contact of the conductive structure with other device structure (e.g., the capacitor structure) is reduced. Further, the fifth groove is formed on a side of the gate material layer along the Z-axis direction and the second part of the conductive structure is formed in the fifth groove such that the space on the side of the gate material layer along the Z-axis direction is efficiently utilized, and this structure layout has a better match with the non-uniform arrangement layout of the semiconductor pillars and is more reasonable.

### Method II:

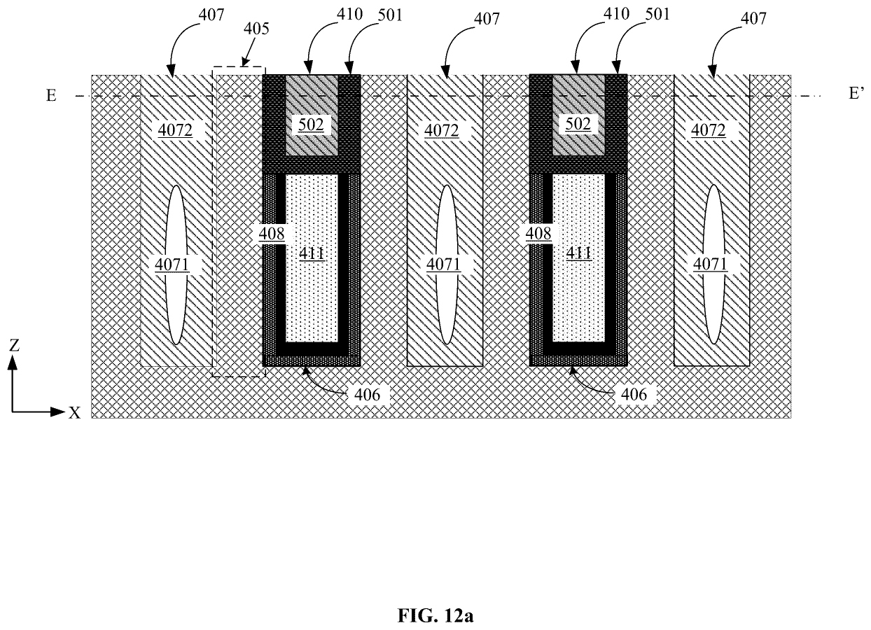

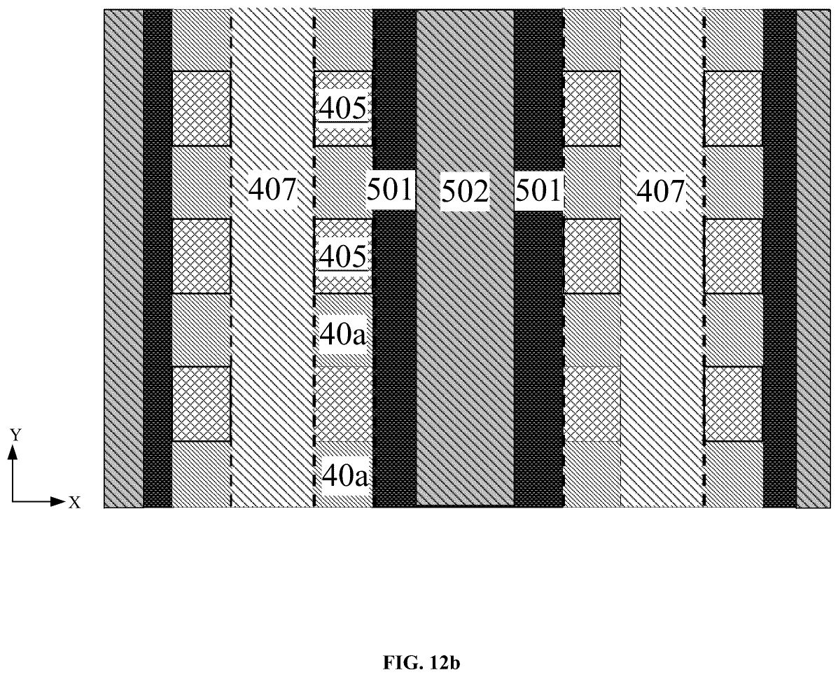

With reference to FIGS. 12a and 12b, FIG. 12b is a cross-sectional schematic view of FIG. 12a along a direction EE′. The method includes: forming a second dielectric layer 501 in the first trench 410, and forming a fourth sub-structure 502 on a side of the second dielectric layer 501 away from the semiconductor pillar 405 along the X-axis direction. The second dielectric layer 501 covers the remaining surface on a side of the semiconductor pillar away from the first isolation structure 407 in the X-axis direction and covers surfaces of the gate material layer 408 and the first sub-structure 411 away from the bottom surface 406 of the semiconductor layer along the Z-axis direction. A composition material of the second dielectric layer 501 includes, but is not limited to, silicon nitride (SiN), and a composition material of the fourth sub-structure 502 includes, but is not limited to, silicon oxide (SiO₂). A method of forming the second dielectric layer 501 and the fourth sub-structure 502 includes, but is not limited to, PVD, CVD, ALD, and the like.

With reference to FIGS. 13a and 13b, FIG. 13b is a cross-sectional schematic view of FIG. 13a along a direction FF′. The method includes: removing part of the semiconductor pillar 405 to form a sixth groove 503. The removing process includes, but is not limited to, dry etching. Here, the size of the remaining semiconductor pillar 405a along the Z-axis direction is greater than the size of the gate material layer 408 along the Z-axis direction.

In some examples, with reference to FIG. 13a, a sidewall of the sixth groove 503 close to the first isolation structure 407 in the X-axis direction is aligned with the surface of the remaining semiconductor pillar 405a away from the gate material layer 408 in the X-axis direction along the Z-axis direction.

With reference to FIG. 13b, the sixth groove 503 has one side along the X-axis direction adjacent to the first isolation structure 407 and another side along the X-axis direction adjacent to the second dielectric layer 501. Two opposite sides of the sixth groove 503 along the Y-axis direction are adjacent to the insulation material 40a that is filled in the first groove.

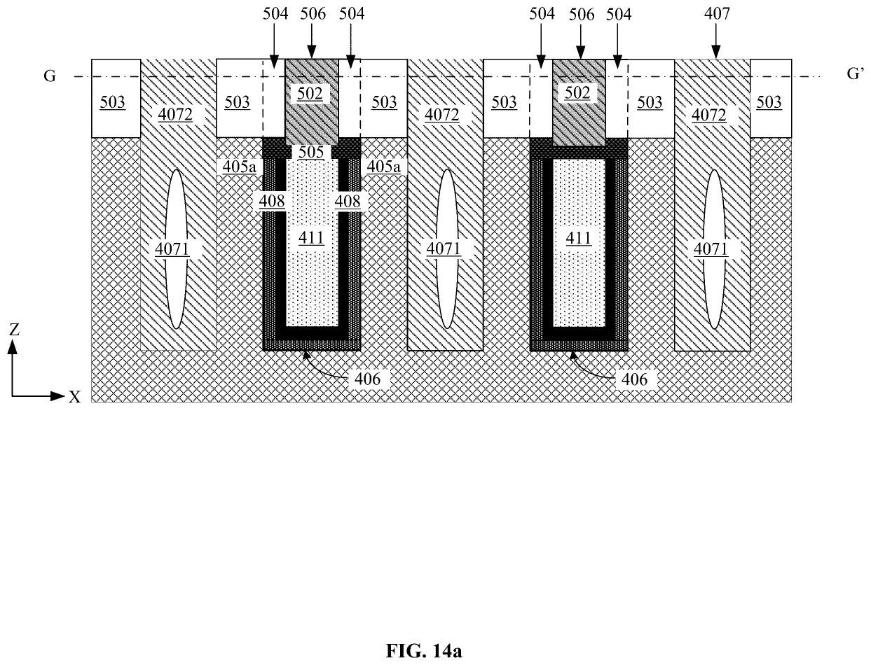

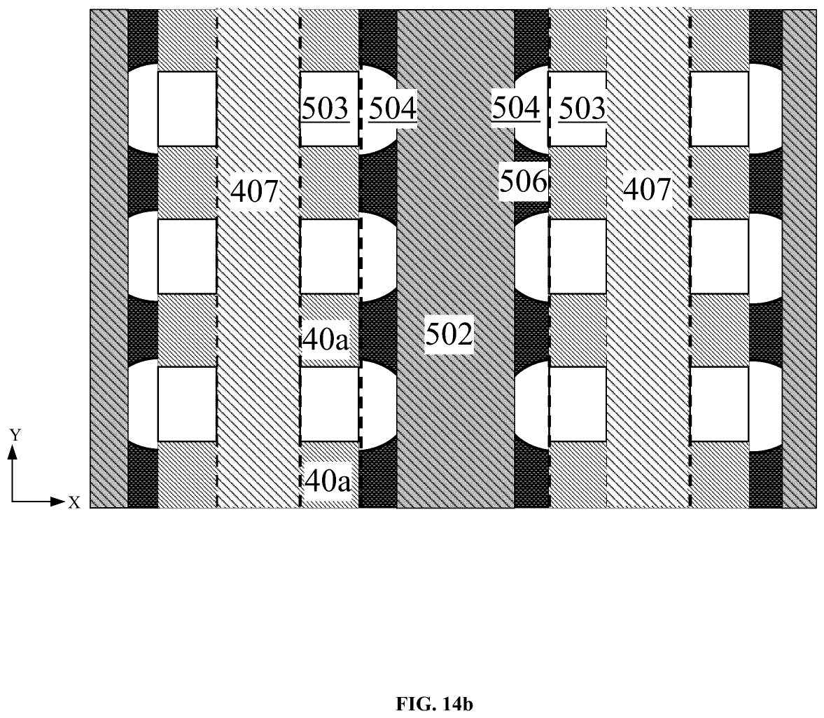

In some examples, with reference to FIGS. 14a and 14b, FIG. 14b is a cross-sectional schematic view of FIG. 14a along a direction GG′. The method includes removing part of the second dielectric layer 501 to form a seventh groove 504 having a curved edge. The sixth groove 503 and the seventh groove 504 together constitute a conductive hole, and the remaining second dielectric layer constitutes a third sub-structure 505. The first sub-structure 411, the third sub-structure 505 and the fourth sub-structure 502 together constitute a second isolation structure 506. It needs to be noted that a method for removing part of the second dielectric layer 501 includes, but is not limited to, wet etching. In an example, the sixth groove 503 is filled with an etchant, such as hot phosphoric acid, and the second dielectric layer 501 is etched by the etchant to remove part of the second dielectric layer 501, and the remaining second dielectric layer constitutes the third sub-structure 505. It should be understood that the amount of the removed second dielectric layer is related to composition of the etchant, concentration of the etchant, and etching temperature, etc., which is not specified in detail in the present disclosure.

Based on a certain etchant, such as hot phosphoric acid, an etching rate of the second dielectric layer 501 is greater than an etching rate of the insulation material 40a, the etching rate of the second dielectric layer 501 is greater than an etching rate of the first isolation structure 407, the etching rate of the second dielectric layer 501 is greater than an etching rate of the remaining semiconductor pillar 405a, and the etching rate of the second dielectric layer 501 is greater than an etching rate of the fourth sub-structure 502. In other words, based on a certain etchant, such as hot phosphoric acid, it is easier to remove the second dielectric layer 501 than to remove the insulation material 40a, the first isolation structure 407, the remaining semiconductor pillar 405a and the fourth sub-structure 502. However, it should be understood that based on an isotropic etching characteristic of wet etching, the formed seventh groove 504 has a curved edge. In other words, a cross-sectional shape of the seventh groove 504 in an XY-plane includes an axisymmetric shape having a curved edge.

The fourth sub-structure 502 may serve as an etch stop layer for wet etching. In an example, when the first dielectric layer between the sixth groove 503 and the fourth sub-structure 502 is removed by the etchant, the fourth sub-structure 502 is used to stop continued etching by the etchant. On this basis, the side of the formed seventh groove 504 away from the sixth groove 503 along the X-axis direction is a straight line side.

Since the etchant may slightly etch a structure surrounding the sixth groove, in other words, a boundary of the sixth groove may expand outwards after the seventh groove is formed, an interface shape of the sixth groove in the XY-plane has an irregular rectangular shape. However, it should be understood that the amount of the structure surrounding the fourth groove etched by the etchant is small, which will not affect the formation of the conductive structure in the subsequent process and also will not affect the performance of the conductive structure. Therefore, the size of the outward expansion of the sixth groove is neglected in the present disclosure.

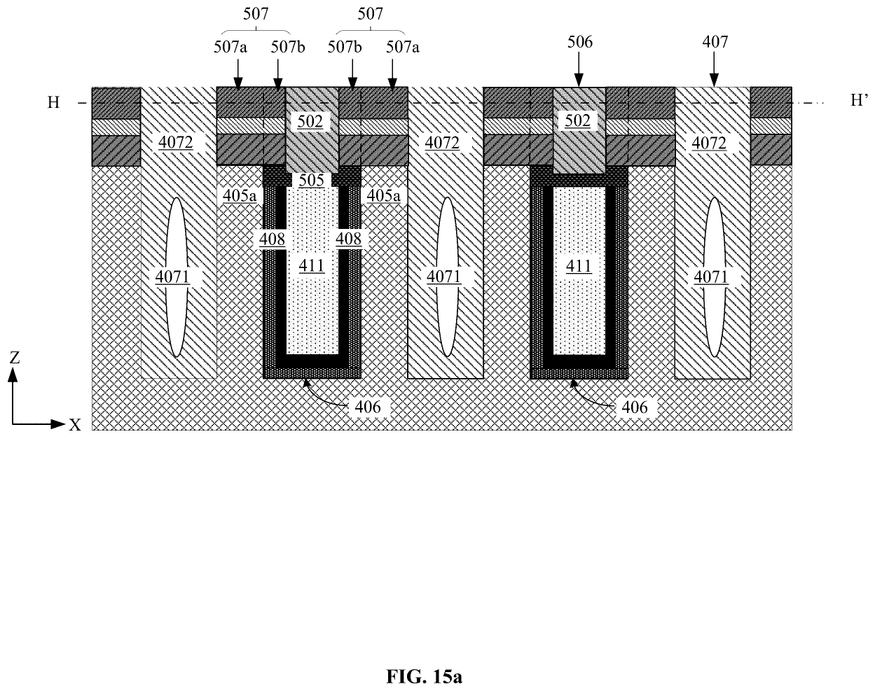

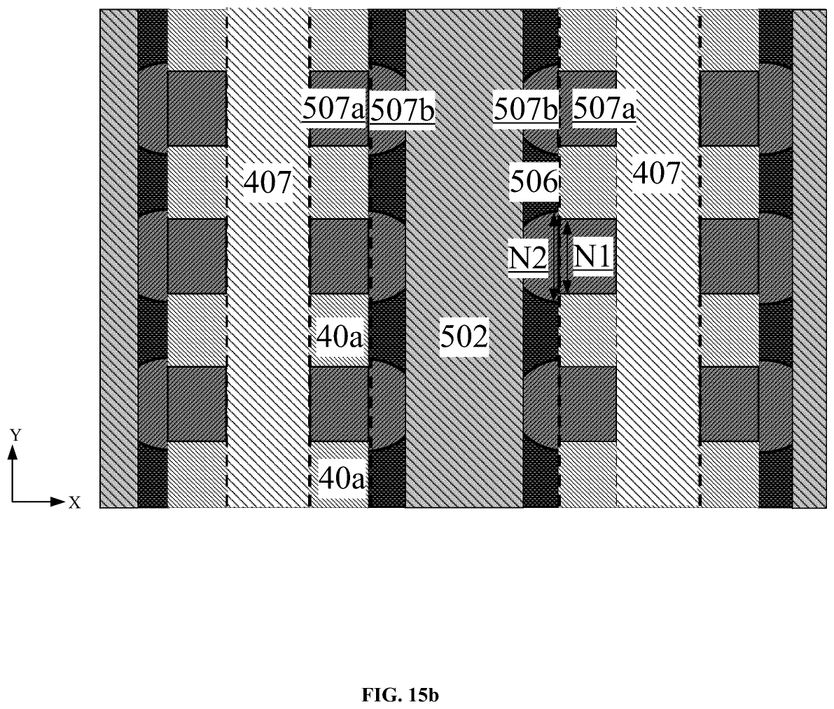

In some examples, with reference to FIGS. 15a and 15b, FIG. 15b is a cross-sectional schematic view of FIG. 15a along a direction HH′. The method further includes forming a first part 507a of the conductive structure 507 in the sixth groove 503 and forming a second part 507b of the conductive structure in the seventh groove 504, where the first part 507a of the conductive structure is in contact with an end of the remaining semiconductor pillar 405a.

In some examples, a size of a portion of the first part 507a of the conductive structure close to the second part 507b of the conductive structure in the Y-axis direction is different from a size of a portion of the second part 507b of the conductive structure close to the first part 507a of the conductive structure in the Y-axis direction.

In an example, with reference to FIG. 15b, the size of the portion of the first part 507a of the conductive structure close to the second part 507b of the conductive structure in the Y-axis direction is a first size N1, and the size of the portion of the second part 507b of the conductive structure close to the first part 507a of the conductive structure in the Y-axis direction is a second size N2. The second size N2 is greater than the first size N1, e.g., N2>N1.

In some examples, as shown in FIG. 15a, a surface of the first isolation structure 407 away from the bottom surface 406 of the semiconductor layer along the Z-axis direction (e.g., a top surface of the first isolation structure 407), a surface of the second isolation structure 506 away from the bottom surface 406 of the semiconductor layer along the Z-axis direction (e.g., a top surface of the second isolation structure 506), a surface of the first part 507a of the conductive structure away from the bottom surface 406 of the semiconductor layer along the Z-axis direction (e.g., a top surface of the first part 507a of the conductive structure), and a surface of the second part 507b of the conductive structure away from the gate material layer along the Z-axis direction (e.g., a top surface of the second part 507b of the conductive structure) are aligned along the X-axis direction.

On the basis that the size of the remaining semiconductor pillar 405a along the Z-axis direction is greater than the size of the gate material layer 408 along the Z-axis direction, the conductive structure 507 and the gate material layer 408 are spaced apart. As shown in FIG. 15a, the conductive structure 507 and the gate material layer 408 are spaced apart by the third sub-structure 505. As such, current leakage between the gate material layer 408 (which is subsequently formed into a gate structure) and the conductive structure 507 may be avoided, thereby improving the reliability of the semiconductor device.

In some examples, the size of the second part 507b of the conductive structure along the X-axis direction is less than the size of the third sub-structure 505 along the X-axis direction. As such, it is easier for the third sub-structure 505 to isolate the conductive structure 507 from the gate material layer 408, thereby further improving the reliability of the semiconductor device.

In some examples, with reference to FIG. 15a, a cross-sectional shape of the third sub-structure 505 between two remaining semiconductor pillars 405a adjacent along the X-axis direction in an XZ-plane is a “concave” shape. In some other examples, the cross-sectional shape of the third sub-structure 505 in the XZ-plane may also be a straight shape or a convex shape, which will not be specified in detail in the present disclosure.

In some examples, the conductive structure may include a polysilicon layer, a metal silicide layer and a conductive metal layer stacked along the Z-axis direction, where the polysilicon layer is in contact with the semiconductor body; or the conductive structure may include a polysilicon layer and a metal silicide layer stacked along the Z-axis direction, where the polysilicon layer is in contact with the semiconductor body; or the conductive structure may include a metal silicide layer in contact with the semiconductor body. The method of forming the conductive structure has been described previously, which is no longer repeated here.

In the examples of the present disclosure, part of the semiconductor pillar is removed to form the sixth groove, and the first part of the conductive structure in direct contact with the remaining semiconductor pillar is formed in the sixth groove. As such, the alignment accuracy of the first part of the conductive structure and the remaining semiconductor pillar can be increased, which in turn reduces the alignment difficulty of them and improves the reliability of the semiconductor device. In addition, by the expansion of the sixth groove, the seventh groove is formed, so that the size of the conductive hole can be increased, which in turns increases the top surface of the conductive structure. As such, the contact area of the conductive structure and other device structure (e.g., the capacitor structure) is increased, and the process difficulty of achieving the contact of the conductive structure with other device structure (e.g., the capacitor structure) is reduced. Further, the seventh groove is formed on a side of the gate material layer along the Z-axis direction and the second part of the conductive structure is formed in the seventh groove such that the space on the side of the gate material layer along the Z-axis direction is efficiently utilized, and this structure layout has a better match with the non-uniform arrangement layout of the semiconductor pillars and is more reasonable. Moreover, during a process of forming the seventh groove, the fourth sub-structure serves as an etch stop layer for wet etching, such that the size of the expansion of the seventh groove is limited. Therefore, the size of the seventh groove can be better controlled, and the controllability of the process is improved.

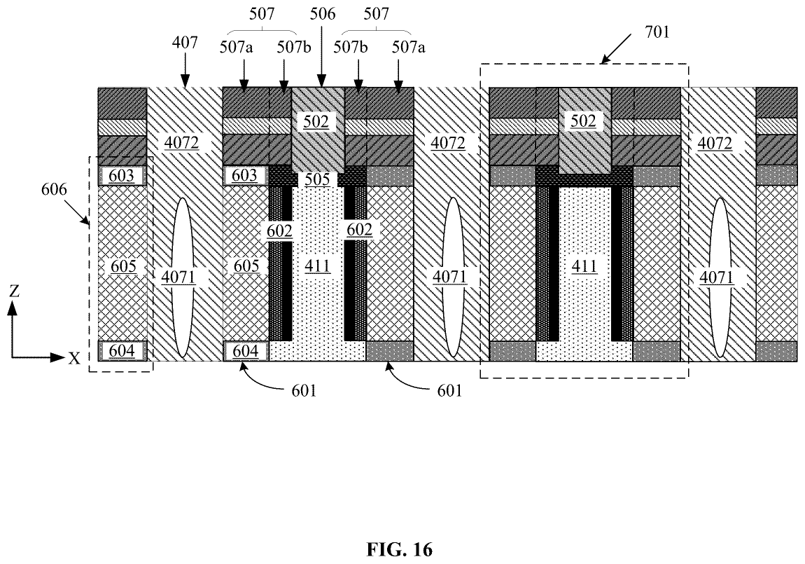

With reference to FIG. 16, the method further includes: turning over the semiconductor layer, and thinning the semiconductor layer to cover a lower end 601 of the remaining semiconductor pillar 405a.

In some examples, the method further includes forming a source and a drain at the upper and lower ends of the remaining semiconductor pillar 405a respectively. A process sequence of forming the source and the drain may be selected according to actual requirements, and an example process sequence of forming the source and the drain is illustrated in the present disclosure.

In an example, the method includes: doping an upper end of the remaining semiconductor pillar 405a away from the bottom surface 406 of the semiconductor layer along the Z-axis direction before forming the conductive structure, to form one of a source 603 or a drain 604; thinning the semiconductor layer after forming the conductive structure, to expose a lower end of the remaining semiconductor pillar opposite to the upper end along the Z-axis direction; and doping the lower end of the remaining semiconductor pillar 405a, to form the other one of the source 603 or the drain 604. A region of the remaining semiconductor pillar 405a between the source 603 and the drain 604 constitutes a channel region 605; and the channel region 605, the source 603 and the drain 604 together constitute a semiconductor body 606.

The positions of the source 603 and the drain 604 may be interchanged. As an example, FIG. 16 illustrates that the source 603 is located at the upper end of the remaining semiconductor pillar 405a and the drain 604 is located at the lower end of the remaining semiconductor pillar 405.

With reference to FIG. 16, the method further includes: removing the gate material layer covering the bottom surface of the semiconductor layer, where the remaining gate material layer constitutes a gate structure 602.

Based on the above methods and operations, a plurality of semiconductor structures arranged in an array along the X-axis direction and the Y-axis direction are formed. As described previously, the plurality of semiconductor structures arranged along the X-axis direction include a first semiconductor structure and a second semiconductor structure arranged alternately; and the first semiconductor structure and the second semiconductor structure disposed adjacently constitute one semiconductor structure group.

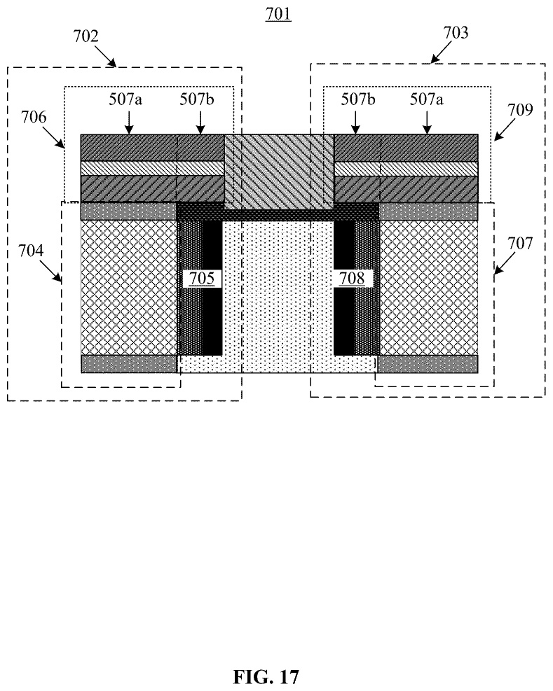

In an example, FIG. 17 is an enlarged schematic view of a semiconductor structure group 701 shown by a dashed box in FIG. 16. The semiconductor structure group 701 includes a first semiconductor structure 702 and a second semiconductor structure 703. The first semiconductor structure 702 includes a first semiconductor body 704, a first gate structure 705 and a first conductive structure 706. The second semiconductor structure 703 includes a second semiconductor body 707, a second gate structure 708 and a second conductive structure 709. The first gate structure 705 is located on a side of the first semiconductor body 704 close to the second semiconductor body 707, and the second gate structure 708 is located on a side of the second semiconductor body 707 close to the first gate structure 705. The first conductive structure 706 is located on a side of the first semiconductor body 704 along the Z-axis direction. The second conductive structure 709 is located on a side of the second semiconductor body 707 in the Z-axis direction. A second part 507b of the first conductive structure 706 is located on a side of a first part 507a of the first conductive structure 706 close to the second conductive structure 709, and a second part 507b of the second conductive structure 709 is located on a side of a first part 507a of the second conductive structure 709 close to the first conductive structure 706.

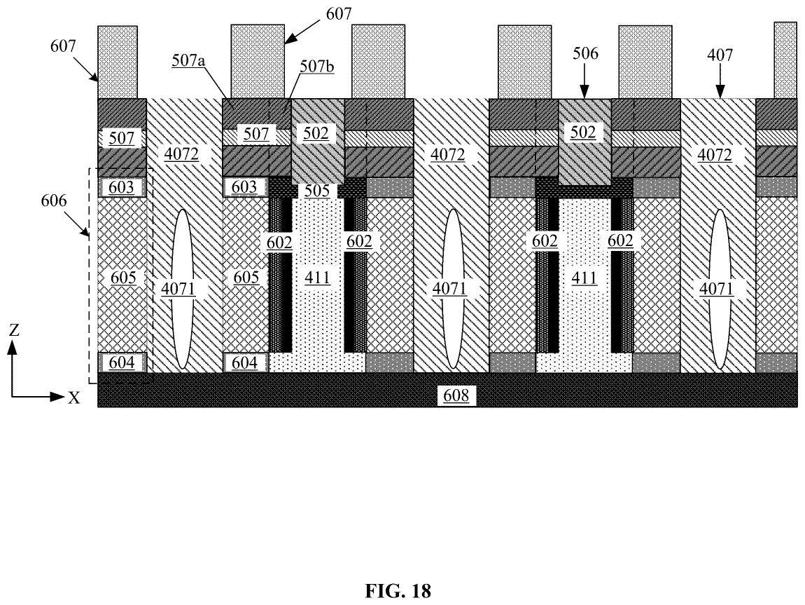

With reference to FIG. 18, the method further includes: forming a capacitor structure 607 connected with an end of the conductive structure 507 away from the semiconductor body 606 along the Z-axis direction. It needs to be noted that the capacitor structure 607 may include a first electrode layer, a dielectric layer covering a surface of the first electrode layer, and a second electrode layer covering a surface of the dielectric layer. The first electrode layer is configured to serve as a lower electrode of the capacitor structure, the dielectric layer is configured to serve as a dielectric of a capacitor, and the second electrode layer is configured to serve as an upper electrode of the capacitor structure. In an example, a composition material of the first electrode layer and the second electrode layer includes, but is not limited to, titanium nitride. A composition material of the dielectric layer includes a high dielectric constant (high-K) material. The high dielectric constant material generally refers to a material of which a dielectric constant is above 3.9, and typically, is significantly higher than this value. In some examples, a composition material of the dielectric layer may include, but is not limited to, aluminum oxide (Al₂O₃), zirconium oxide (ZrO₂), hafnium oxide (HfO₂), etc. Methods of forming the first electrode layer, the dielectric layer and the second electrode layer may include, but are not limited to, PVD, CVD, ALD, and the like.

In some examples, the capacitor structure may also have a variety of different shapes, e.g., a cylinder-shaped or pillar-shaped capacitor. That is, the capacitor structure may include a cup-shaped capacitor CUP, a cylinder-shaped capacitor CYL, and a pillar-shaped capacitor PIL. The shape of the capacitor structure may be selected according to actual requirements, which will not be specified in detail in the present disclosure.

In some examples, a surface of the first part 507a of the conductive structure away from the semiconductor body 606 along the Z-axis direction (e.g., a top surface of the first part 507a of the conductive structure) and at least part of a surface of the second part 507b of the conductive structure away from the semiconductor body 606 along the Z-axis direction (e.g., a top surface of the second part 507b of the conductive structure) are in contact with the capacitor structure 607. In other words, the capacitor structure 607 may be only in contact with all/part of the top surface of the first part 507a of the conductive structure, or may also be only in contact with all/part of the top surface of the second part 507b of the conductive structure, or may also be in contact with all/part of surfaces of the first part 507a of the conductive structure and the second part 507b of the conductive structure. As such, a process window of the conductive structure 507 in contact with the capacitor structure 607 may be enlarged, the process difficulty may be reduced, and the reliability of the semiconductor device may be improved.

The second isolation structure shown in FIG. 18 is a second isolation structure (including the first sub-structure 411, the third sub-structure 505 and the fourth sub-structure 502) formed by method II. However, it should be understood that the above example illustration is only used to illustrate the present disclosure rather than to define the scope of the present disclosure.

With continued reference to FIG. 18, the method further includes: forming a plurality of bit lines 608 extending along the X-axis direction and spaced apart along the Y-axis direction, where each bit line 608 is connected with an end of one row of the semiconductor bodies 606 away from the conductive structure 507 along the Z-axis direction. In an example, each bit line 608 is connected with the drain 604 of each semiconductor body 606 in one row of semiconductor bodies 606 disposed along the X-axis direction. A composition material of the bit line 608 includes, but is not limited to, tungsten (W). A method of forming the bit line includes, but is not limited to, PVD, CVD, ALD, and the like.

In the examples of the present disclosure, by forming the conductive structure connected with the semiconductor body on a side of the semiconductor body along the first direction, self-alignment of the conductive structure and the semiconductor body can be achieved. As such, alignment accuracy of the first part of the conductive structure with the semiconductor body can be improved; alignment difficulty of them is reduced; reliability of the semiconductor device is improved; manufacturing time and cost are saved; and process speed and efficiency are increased. In another aspect, the conductive structure includes the first part connected with the semiconductor body, and the second part arranged in juxtaposition with the first part along the second direction. As such, the purpose of increasing the volume/surface area of the conductive structure can be achieved; thus, the contact area of the conductive structure with other external structure (e.g., the capacitor structure) can be increased and the reliability of the semiconductor device can be improved. In further another aspect, the size of the portion of the first part close to the second part in the third direction is different from the size of the portion of the second part close to the first part in the third direction. As such, the conductive structure and the semiconductor body may have a better matched and more reasonable structure layout.

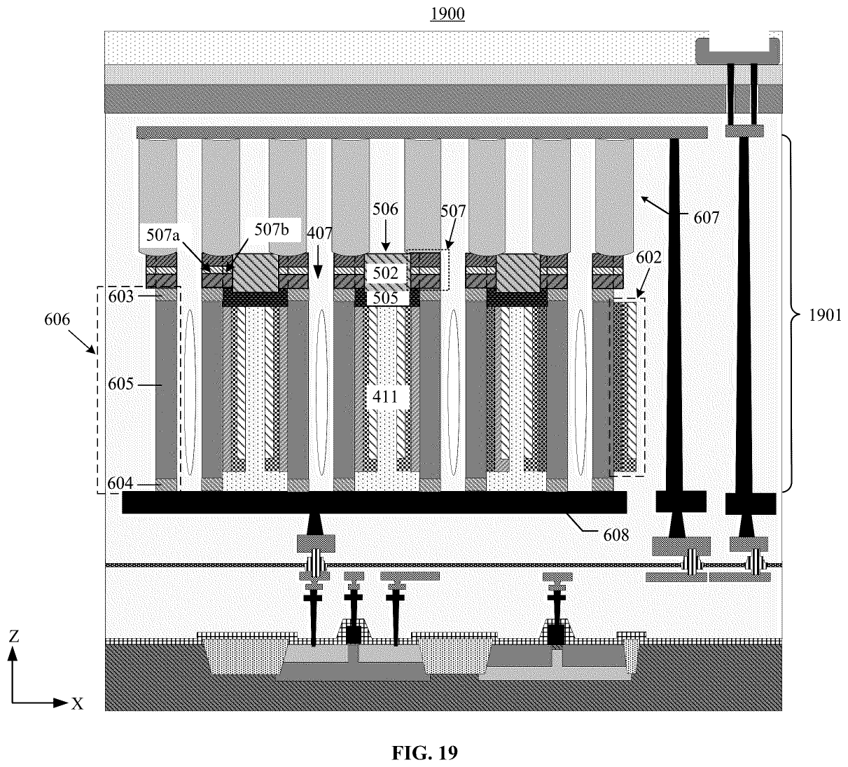

Based on the manufacturing method of the semiconductor device, the examples of the present disclosure further provide a semiconductor device. With reference to FIG. 19, the semiconductor device 1900 includes: a semiconductor structure 1901, where the semiconductor structure 1901 includes a semiconductor body 606 extending along a first direction; and a conductive structure 507 located on a side of the semiconductor body along the first direction, where the conductive structure 507 includes a first part 507a and a second part 507b arranged along a second direction; the first part 507a is in contact with an end of the semiconductor body 606; a size of a portion of the first part close to the second part in a third direction is different from a size of a portion of the second part close to the first part in the third direction; the second direction intersects the third direction, and the first direction is perpendicular to a plane formed by the second direction and the third direction.

In some examples, the size of the portion of the first part close to the second part in the third direction is a first size; the size of the portion of the second part close to the first part in the third direction is a second size; and the second size is greater than the first size.

In some examples, a cross-sectional shape of the first part in the plane includes a square; and a cross-sectional shape of the second part in the plane includes an axisymmetric shape having a curved edge.

In some examples, a spacing distance in the second direction between a surface of the first part away from the second part in the second direction and a surface of the semiconductor body away from the second part in the second direction is less than a preset value.

In some examples, with reference to FIG. 19, the semiconductor structure further includes: a gate structure 602 located on a side of the semiconductor body 606 close to the second part in the second direction, where a surface of the gate structure 602 close to the second part 507b along the first direction is spaced apart from a surface of the second part close to the gate structure along the first direction.

In some examples, with reference to FIG. 19, the semiconductor structure further includes: a first isolation structure 407 located on a side of the semiconductor body away from the second part in the second direction; and a second isolation structure 506 located on a side of the gate structure away from the semiconductor body along the second direction, where the second isolation structure is in contact with a surface of the second part away from the first part, the surface of the second part close to the gate structure along the first direction, and the surface of the gate structure close to the second part along the first direction.

In some other examples, the second isolation structure includes a first sub-structure and a second sub-structure arranged along the first direction, where the first sub-structure is located on the side of the gate structure away from the semiconductor body along the second direction; and the second sub-structure is located on a side of the second part away from the first part, and located between the surface of the gate structure close to the second part along the first direction and the surface of the second part close to the gate structure along the first direction.

In some examples, with reference to FIG. 19, the second isolation structure 506 includes a first sub-structure 411, a third sub-structure 505 and a fourth sub-structure 502 arranged along the first direction, where the first sub-structure 411 is located on the side of the gate structure 602 away from the semiconductor body 606 along the second direction; the third sub-structure 505 is located between the surface of the gate structure 602 close to the second part 507b along the first direction and the surface of the second part 507b close to the gate structure 602 along the first direction; and the fourth sub-structure 502 is located on a side of the second part 507b away from the first part 507a.

In some examples, a composition material of the third sub-structure is different from a composition material of the fourth sub-structure.

In some examples, a size of the second part along the second direction is less than a size of the third sub-structure along the second direction.

In some examples, the side of the second part away from the first part along the second direction is a straight line side extending along the third direction.

In some examples, the conductive structure is located between the first isolation structure and the fourth sub-structure, and is in contact with a side of the third sub-structure away from the gate structure along the first direction.

In some examples, the first isolation structure includes a first end face and a second end face that are opposite along the first direction, and the second isolation structure includes a third end face and a fourth end face that are opposite along the first direction; and the first end face, the third end face, a surface of the first part away from the semiconductor body along the first direction, and a surface of the second part away from the gate structure along the first direction are aligned along the second direction.

In some examples, the conductive structure includes a polysilicon layer, a metal silicide layer and a conductive metal layer stacked along the first direction; or the conductive structure includes a polysilicon layer and a metal silicide layer stacked along the first direction; or the conductive structure includes a metal silicide layer in contact with the semiconductor body.

In some examples, with reference to FIG. 19, the semiconductor body 606 includes: a channel region 605; and a source 603 and a drain 604 located on two sides of the channel region 605 respectively along the first direction.

In some examples, with reference to FIG. 19, the semiconductor structure further includes: a capacitor structure 607 connected with an end of the conductive structure 507 away from the semiconductor body 606 in the first direction.

In some examples, the capacitor structure includes a fifth end face and a sixth end face that are opposite along the first direction; and the surface of the first part away from the semiconductor body along the first direction and at least part of a surface of the second part away from the semiconductor body along the first direction are in contact with the fifth end face.

In some examples, the semiconductor device includes a plurality of semiconductor structures arranged in an array along the second direction and the third direction, where the plurality of semiconductor structures arranged along the second direction include a first semiconductor structure and a second semiconductor structure arranged alternately; and the first semiconductor structure and the second semiconductor structure disposed adjacently constitute one semiconductor structure group.

In some examples, the first semiconductor structure includes a first semiconductor body, a first gate structure and a first conductive structure; the second semiconductor structure includes a second semiconductor body, a second gate structure and a second conductive structure; the first gate structure is located on a side of the first semiconductor body close to the second semiconductor body, and the second gate structure is located on a side of the second semiconductor body close to the first gate structure; and a second part of the first conductive structure is located on a side of a first part of the first conductive structure close to the second conductive structure, and a second part of the second conductive structure is located on a side of a first part of the second conductive structure close to the first conductive structure.

In some examples, with reference to FIG. 19, the semiconductor device further includes: a plurality of bit lines 608 extending along the second direction and spaced apart along the third direction, where each of the plurality of bit lines 608 is connected with an end of one row of the semiconductor bodies 606 away from the conductive structure 507 along the first direction.

According to one aspect of the present disclosure, a memory system is provided, including: the semiconductor device described in the above examples of the present disclosure; and a memory controller connected with the semiconductor device and configured to control the semiconductor device.

It needs to be noted that the conductive structure 507 shown in FIG. 19 is formed by method II described in the above examples of the present disclosure. In some other semiconductor devices, the conductive structure may also be formed by the method I described in the above examples, which will not be described in the present disclosure.

The above descriptions are merely specific implementations of the present disclosure, and the protection scope of the present disclosure is not limited to those. Any variation or replacement that may be readily figured out by those skilled in the art within the technical scope disclosed by the present disclosure shall fall within the protection scope of the present disclosure. Therefore, the protection scope of the present disclosure shall be defined by the protection scope of the claims.

What is claimed is:

1. A semiconductor device, comprising:
a semiconductor structure comprising a semiconductor body extending along a first direction; and
a conductive structure located on a side of the semiconductor body along the first direction,
wherein the conductive structure comprises a first part and a second part arranged along a second direction; the first part is in contact with an end of the semiconductor body; a size of a portion of the first part close to the second part in a third direction is different from a size of a portion of the second part close to the first part in the third direction; the second direction intersects the third direction, and the first direction is perpendicular to a plane formed by the second direction and the third direction.

2. The semiconductor device of claim 1, wherein
the size of the portion of the first part close to the second part in the third direction is a first size;
the size of the portion of the second part close to the first part in the third direction is a second size; and
the second size is greater than the first size.

3. The semiconductor device of claim 1, wherein the semiconductor structure further comprises:
a gate structure located on a side of the semiconductor body close to the second part in the second direction, wherein a surface of the gate structure close to the second part along the first direction is spaced apart from a surface of the second part close to the gate structure along the first direction.

4. The semiconductor device of claim 3, wherein the semiconductor structure further comprises:
a first isolation structure located on a side of the semiconductor body away from the second part in the second direction; and
a second isolation structure located on a side of the gate structure away from the semiconductor body along the second direction, wherein the second isolation structure is in contact with a surface of the second part away from the first part, the surface of the second part close to the gate structure along the first direction, and the surface of the gate structure close to the second part along the first direction.

5. The semiconductor device of claim 4, wherein the second isolation structure comprises a first sub-structure and a second sub-structure arranged along the first direction,
wherein the first sub-structure is located on the side of the gate structure away from the semiconductor body along the second direction; and
the second sub-structure is located on a side of the second part away from the first part, and located between the surface of the gate structure close to the second part along the first direction and the surface of the second part close to the gate structure along the first direction.

6. The semiconductor device of claim 4, wherein the second isolation structure comprises a first sub-structure, a third sub-structure and a fourth sub-structure arranged along the first direction,
wherein the first sub-structure is located on the side of the gate structure away from the semiconductor body along the second direction;
the third sub-structure is located between the surface of the gate structure close to the second part along the first direction and the surface of the second part close to the gate structure along the first direction; and
the fourth sub-structure is located on a side of the second part away from the first part.

7. The semiconductor device of claim 5, wherein the conductive structure comprises a polysilicon layer, a metal silicide layer and a conductive metal layer stacked along the first direction; or
the conductive structure comprises a polysilicon layer and a metal silicide layer stacked along the first direction; or
the conductive structure comprises a metal silicide layer in contact with the semiconductor body.

8. The semiconductor device of claim 1, wherein the semiconductor structure further comprises:
a capacitor structure connected with an end of the conductive structure away from the semiconductor body in the first direction.

9. The semiconductor device of claim 1, further comprising:
a plurality of the semiconductor structures arranged in an array along the second direction and the third direction,
wherein the plurality of the semiconductor structures arranged along the second direction comprise a first semiconductor structure and a second semiconductor structure arranged alternately;
and the first semiconductor structure and the second semiconductor structure disposed adjacently constitute one semiconductor structure group,
wherein the first semiconductor structure comprises a first semiconductor body, a first gate structure and a first conductive structure; the second semiconductor structure comprises a second semiconductor body, a second gate structure and a second conductive structure;
wherein the first gate structure is located on a side of the first semiconductor body close to the second semiconductor body, and the second gate structure is located on a side of the second semiconductor body close to the first gate structure, and
wherein a second part of the first conductive structure is located on a side of a first part of the first conductive structure close to the second conductive structure, and a second part of the second conductive structure is located on a side of a first part of the second conductive structure close to the first conductive structure.

10. A memory system, comprising:
a semiconductor device, comprising:
a semiconductor structure comprising a semiconductor body extending along a first direction; and
a conductive structure located on a side of the semiconductor body along the first direction,
wherein the conductive structure comprises a first part and a second part arranged along a second direction; the first part is in contact with an end of the semiconductor body; a size of a portion of the first part close to the second part in a third direction is different from a size of a portion of the second part close to the first part in the third direction; the second direction intersects the third direction, and the first direction is perpendicular to a plane formed by the second direction and the third direction; and
a memory controller connected with the semiconductor device and configured to control the semiconductor device.

11. A method of manufacturing a semiconductor device, comprising:
forming a semiconductor body extending along a first direction; and
forming a conductive structure located on a side of the semiconductor body along the first direction, the semiconductor body and the conductive structure being configured to form a semiconductor structure,
wherein the conductive structure comprises a first part and a second part arranged along a second direction; the first part is in contact with an end of the semiconductor body; a size of a portion of the first part close to the second part in a third direction is different from a size of a portion of the second part close to the first part in the third direction; the second direction intersects the third direction, and the first direction is perpendicular to a plane formed by the second direction and the third direction.

12. The method of claim 11, wherein forming a semiconductor body extending along a first direction comprises:
forming, in a semiconductor layer, a plurality of first grooves extending along the second direction and spaced apart along the third direction, and a plurality of second grooves and a plurality of third grooves extending along the third direction and alternately spaced apart along the second direction, to form a plurality of semiconductor pillars extending along the first direction, the semiconductor pillars being configured to form the semiconductor body;
forming a first isolation structure in the second groove;
forming a gate material layer in the third groove, wherein the gate material layer covers part of a surface of the semiconductor pillar and covers an exposed bottom surface of the semiconductor layer; and
forming a first sub-structure on a side of the gate material layer away from the semiconductor pillar along the second direction.

13. The method of claim 12, further comprising:
filling the third grooves with a first dielectric layer, wherein the first dielectric layer covers a remaining surface of the semiconductor pillar and covers surfaces of the gate material layer and the first sub-structure away from the bottom surface of the semiconductor layer along the first direction; and
removing part of the semiconductor pillar to form a fourth groove, wherein a size of a remaining semiconductor pillar along the first direction is greater than a size of the gate material layer along the first direction.

14. The method of claim 13, further comprising:
removing part of the first dielectric layer to form a fifth groove having a curved edge,
wherein a remaining first dielectric layer constitutes a second sub-structure; and the first sub-structure and the second sub-structure constitute a second isolation structure.

15. The method of claim 14, wherein forming the conductive structure comprises:
forming the first part of the conductive structure in the fourth groove and forming the second part of the conductive structure in the fifth groove, wherein the first part is in contact with an end of the remaining semiconductor pillar.

16. The method of claim 12, further comprising:
forming a second dielectric layer in the third grooves, wherein the second dielectric layer covers a remaining surface of the semiconductor pillar and covers the surfaces of the gate material layer and the first sub-structure away from the bottom surface of the semiconductor layer along the first direction;
forming a fourth sub-structure on a side of the second dielectric layer away from the semiconductor pillar along the second direction; and
removing part of the semiconductor pillar to form a sixth groove, wherein a size of a remaining semiconductor pillar along the first direction is greater than a size of the gate material layer along the first direction.

17. The method of claim 16, further comprising:
removing part of the second dielectric layer to form a seventh groove having a curved edge,
wherein a remaining second dielectric layer constitutes a third sub-structure; and the first sub-structure, the third sub-structure and the fourth sub-structure constitute a second isolation structure.

18. The method of claim 17, wherein forming the conductive structure comprises:
forming a first part of the conductive structure in the sixth groove and forming a second part of the conductive structure in the seventh groove, wherein the first part is in contact with an end of the remaining semiconductor pillar.

19. The method of claim 15, further comprising:
removing the gate material layer covering the bottom surface of the semiconductor layer to form a gate structure.

20. The method of claim 19, further comprising:
forming a capacitor structure connected with an end of the conductive structure away from the semiconductor body along the first direction.
